(19) United States
(12) Patent Application Publication
(10) Pub. No.: US 2015/0070604 A1
(43) Pub. Date: Mar. 12, 2015

(54) TOUCH DEVICE

(71) Applicant: WINTEK CORPORATION, Taichung City (TW)

(72) Inventors: Ming-Wu Chen, Nantou County (TW); Kuo-Chang Su, Taichung City (TW); Chin-Chang Liu, Taichung City (TW); Wen-Chun Wang, Taichung City (TW)

(21) Appl. No.: 14/480,615

(22) Filed: Sep. 8, 2014

(30) Foreign Application Priority Data
Sep. 9, 2013 (TW) 102216935
Jan. 15, 2014 (TW) 103101495

(51) Int. Cl. H03K 17/96; G06F 1/16

(52) U.S. Cl. CPC H03K 17/9622; G06F 1/1643; H03K 2017/9615; H03K 2217/960755; H03K 2217/960765; H03K 2217/96077; H03K 2217/960705
USPC 349/12; 200/5 R

(57) ABSTRACT

A touch device includes a cover substrate, a thin substrate, a first adhesive layer, a first touch sensing unit and a first outer unit. The thin substrate is disposed opposite to the cover substrate. The thin substrate has a first surface and a second surface opposite to the first surface. The first surface faces the cover substrate. A thickness of the thin substrate is thicker than or equal to 0.05 millimeter and thinner than or equal to 0.25 millimeter. The first adhesive layer is disposed between the cover substrate and the thin substrate. The first touch sensing unit is disposed on the thin substrate. The first outer unit is electrically connected to the first touch sensing unit.

### BACKGROUND OF THE INVENTION

1. Field of the Invention

The present invention generally relates to a touch device, and more particularly, to a touch device including a touch sensing unit disposed on a thin substrate.

2. Description of the Prior Art

Touch sensing technologies are well-developed in recent years. Many consumer electronics, such as mobile phones and tablet PCs, are integrated with touch sensing functions. In those consumer electronics, display panels are mainly used to be integrated with the touch sensing function and perform as touch display panels. According to differences in structure designs, the touch display panels may include an out-cell type touch display panel, an in-cell type touch display panel, and an on-cell type touch display panel. In the out-cell type touch display panel, an independent touch panel is attached to a normal display panel. In the on-cell type and the in-cell type touch display panels, the touch sensing units are disposed on an inner side or an outer side of the substrate in the display panel. No matter what kind of the touch panel is, the thickness of the substrate generally used in the ordinary touch panel ranges between 0.4 millimeter and 0.55 millimeter, and the thickness condition cannot satisfy the thinner and compact demands of the touch panels in the related markets.

### SUMMARY OF THE INVENTION

It is one of the objectives of the present invention to provide a touch device. A thin substrate having a thickness thicker than or equal to 0.05 millimeter and thinner than or equal to 0.25 millimeter is employed to achieve the purposes of lightweight and thinner designs.

To achieve the purposes described above, a preferred embodiment of the present invention provides a touch device. The touch device includes a cover substrate, a thin substrate, a first adhesive layer, a first touch sensing unit and a first outer unit. The thin substrate is disposed opposite to the cover substrate. The thin substrate has a first surface and a second surface opposite to the first surface. The first surface faces the cover substrate, and a thickness of the thin substrate is thicker than or equal to 0.05 millimeter and thinner than or equal to 0.25 millimeter. The first adhesive layer is disposed between the cover substrate and the thin substrate. The first touch sensing unit is disposed on the thin substrate. The first outer unit is electrically connected to the first touch sensing unit.

In the touch device of the present invention, the touch sensing unit is disposed on the thin substrate having a thickness thicker than or equal to 0.05 millimeter and thinner than or equal to 0.25 millimeter, and the touch panel may become thinner, compact and lightweight accordingly.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a touch device according to a first embodiment of the present invention.

FIG. 2 is a schematic diagram illustrating a self-capacitance type first touch sensing unit according to the first embodiment of the present invention.

FIG. 3 is a schematic diagram illustrating a mutual-capacitance type first touch sensing unit according to the first embodiment of the present invention.

FIG. 4 is a schematic diagram illustrating another mutual-capacitance type first touch sensing unit according to the first embodiment of the present invention.

FIG. 5 is a schematic diagram illustrating another mutual-capacitance type first touch sensing unit according to the first embodiment of the present invention.

FIG. 6 is a schematic diagram illustrating a touch device according to a second embodiment of the present invention.

FIG. 7 is a schematic diagram illustrating a touch device according to a third embodiment of the present invention.

FIG. 8 is a schematic diagram illustrating a touch device according to a fourth embodiment of the present invention.

FIG. 9 is a schematic diagram illustrating a touch device according to a fifth embodiment of the present invention.

FIG. 10 is a schematic diagram illustrating a touch device according to a sixth embodiment of the present invention.

FIG. 11 is a schematic diagram illustrating a touch device according to a seventh embodiment of the present invention.

FIG. 12 is a schematic diagram illustrating a touch device according to an eighth embodiment of the present invention.

FIG. 13 is a schematic diagram illustrating a touch device according to a ninth embodiment of the present invention.

FIG. 14 is a schematic diagram illustrating a touch device according to a tenth embodiment of the present invention.

FIG. 15 is a schematic diagram illustrating a touch device according to an eleventh embodiment of the present invention.

FIG. 16 is a schematic diagram illustrating a touch device according to a twelfth embodiment of the present invention.

FIG. 17 is a schematic diagram illustrating a touch device according to a thirteen embodiment of the present invention.

FIG. 18 is a schematic diagram illustrating a touch device according to a fourteenth embodiment of the present invention.

FIG. 19 is a schematic diagram illustrating a touch device according to a fifteenth embodiment of the present invention.

FIG. 20 is a schematic diagram illustrating a touch device according to a sixteenth embodiment of the present invention.

FIG. 21 is a schematic diagram illustrating a touch device according to a seventeenth embodiment of the present invention.

FIG. 22, FIG. 23, FIG. 24, FIG. 25, FIG. 26, FIG. 27 and FIG. 28 are schematic diagrams illustrating allocation conditions of a cover substrate and a protection layer according to the seventeenth embodiment of the present invention.

FIG. 29 is a schematic diagram illustrating a touch device according to an eighteenth embodiment of the present invention.

FIG. 30 is a schematic diagram illustrating a touch device according to a nineteenth embodiment of the present invention.

FIG. 31 is a schematic diagram illustrating a touch device according to a twentieth embodiment of the present invention.

FIG. 32 is a schematic diagram illustrating a touch device according to a twenty-first embodiment of the present invention.

FIG. 33 is a schematic diagram illustrating a touch device according to a twenty-second embodiment of the present invention.

FIG. 34 is a schematic diagram illustrating a touch device according to a twenty-third embodiment of the present invention.

FIG. 35 is a schematic diagram illustrating a touch device according to a twenty-fourth embodiment of the present invention.

FIG. 36 is a schematic diagram illustrating a touch device according to a twenty-fifth embodiment of the present invention.

FIG. 37 is a schematic diagram illustrating a touch device according to a twenty-sixth embodiment of the present invention.

FIG. 38 is a schematic diagram illustrating a touch device according to a twenty-seventh embodiment of the present invention.

FIG. 39 is a schematic diagram illustrating a touch device according to a twenty-eighth embodiment of the present invention.

FIG. 40 is a schematic diagram illustrating a touch device according to a twenty-ninth embodiment of the present invention.

FIG. 41 is a schematic diagram illustrating a touch device according to a thirtieth embodiment of the present invention.

FIG. 42 is a schematic diagram illustrating a touch device according to a thirty-first embodiment of the present invention.

### DETAILED DESCRIPTION

To provide a better understanding of the present invention to the skilled users in the technology of the present invention, preferred embodiments will be detailed as follows. The preferred embodiments of the present invention are illustrated in the accompanying drawings with numbered elements to elaborate the contents and effects to be achieved.

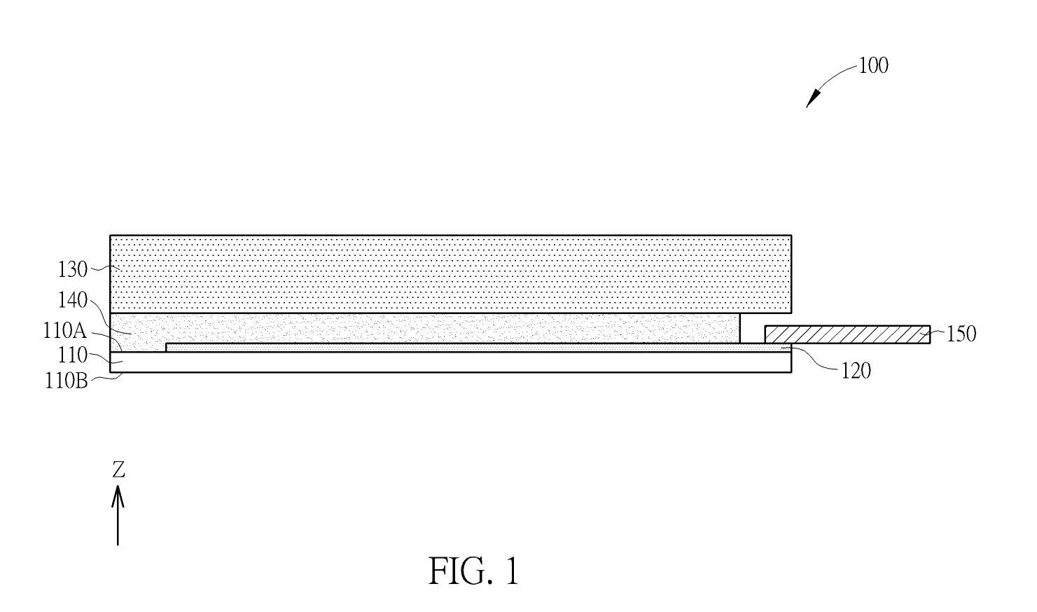

FIG. 1 is a schematic diagram illustrating a touch device according to a first embodiment of the present invention. Please note that the figures are only for illustration and the figures may not be to scale. The scale may be further modified according to different design considerations. As shown in FIG. 1, a touch device 100 is provided in the first preferred embodiment of the present invention. The touch device 100 includes a cover substrate 130, a thin substrate 110, a first adhesive layer 140, a first touch sensing unit 120 and a first outer unit 150. The thin substrate 110 is disposed opposite to the cover substrate 130. The thin substrate 110 has a first surface 110A and a second surface 110B opposite to the first surface 110A. The first surface 110A faces the cover substrate 130, and a thickness of the thin substrate 100 is thicker than or equal to 0.05 millimeter and thinner than or equal to 0.25 millimeter. The first adhesive layer 140 is disposed between the cover substrate 130 and the thin substrate 110. The first touch sensing unit 120 is disposed on the thin substrate 110. The first outer unit 150 is electrically connected to the first touch sensing unit 120. In this embodiment, the first touch sensing unit 120 and at least a part of the first outer unit 150 are disposed on a side of the first surface 110A, and a thickness of the first adhesive layer 140 is thicker than or equal to a thickness of the first outer unit 150 preferably, but not limited thereto.

In this embodiment, the thin substrate 110 may include a thin glass substrate, a thin plastic substrate, a thin glass-plastic composite substrate or other thin substrate made of appropriate materials. It is worth noting that the thin substrate 110 of the present invention is a thin glass substrate preferably so as to provide better process properties and light transmittance along with the thinner and lightweight properties, but not limited thereto. The thin substrate 110 may be flexible, and roll-to-roll process may be employed accordingly so as to enhance the application variety and the manufacturing convenience. Additionally, the cover substrate 130 may include a glass cover substrate, a plastic cover substrate or other cover substrates made of materials with high mechanical strength and used to protect, cover or decorate the corresponding device. The cover substrate 130 may be flat, curved or a combination of flat and curved structures, such as a 2.5D glass, but not limited thereto. The first adhesive layer 140 may include a liquid optical clear adhesive (LOCA), a solid optical clear adhesive (OCA), a pressure sensitive adhesive (PSA) or other appropriate adhesive materials. The first outer unit 150 may include a flexible printed circuit (FPC), an integrated circuit or other outer unit electrically connected to the first touch sensing unit 120. The first touch sensing unit 120 in this embodiment may be made of a transparent conductive material, conductive mesh or other appropriate conductive materials.

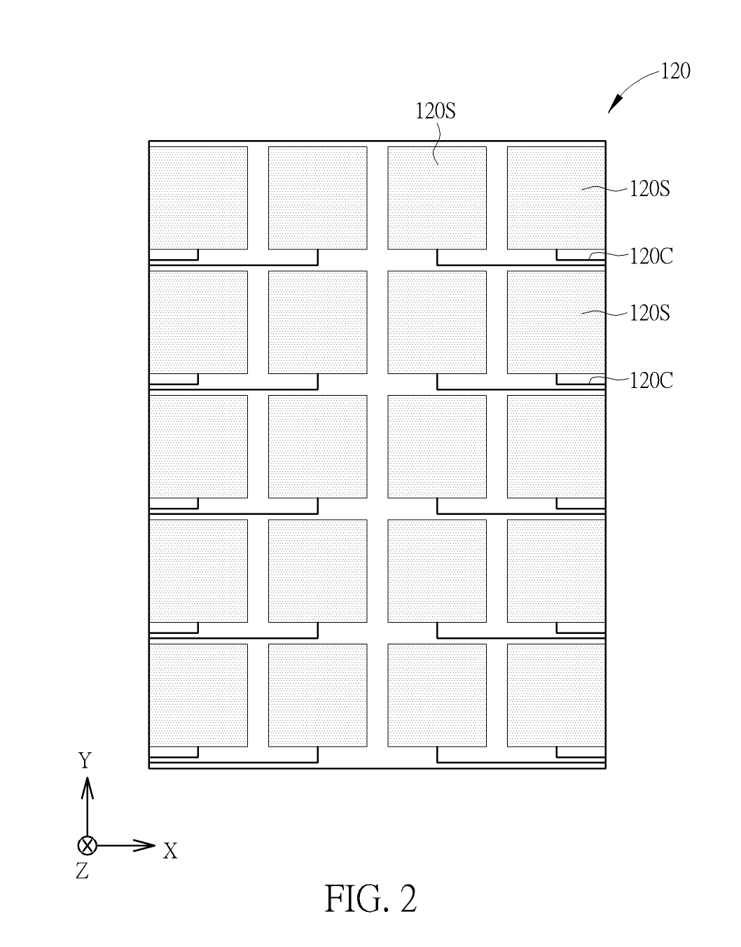

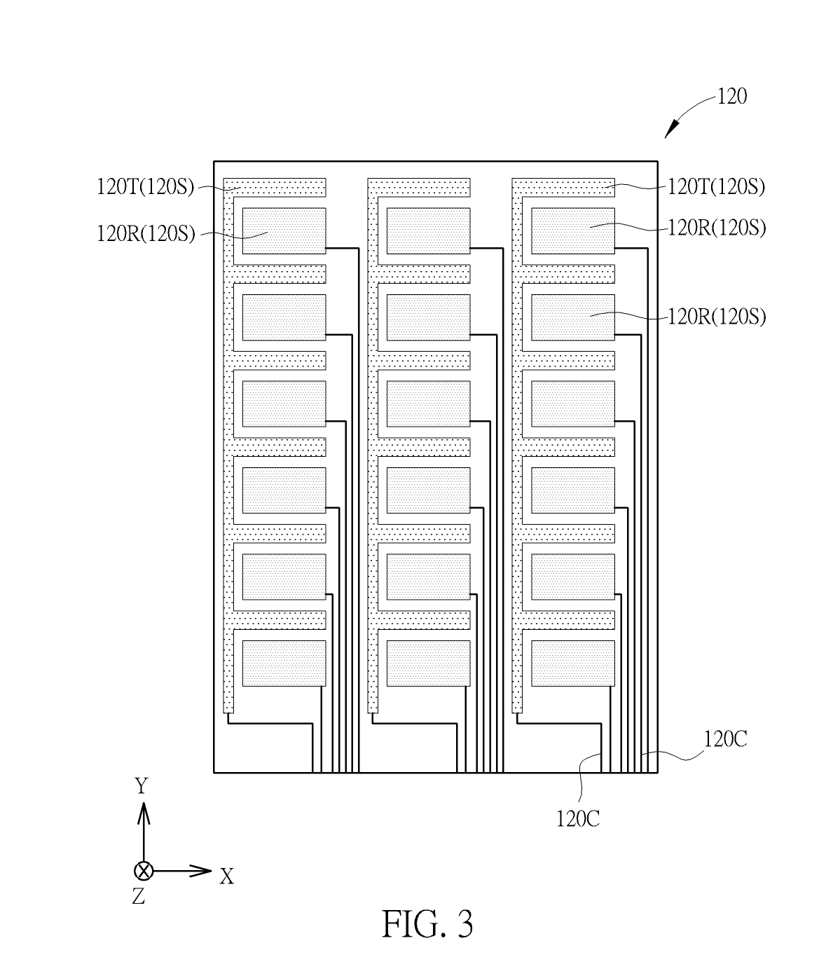

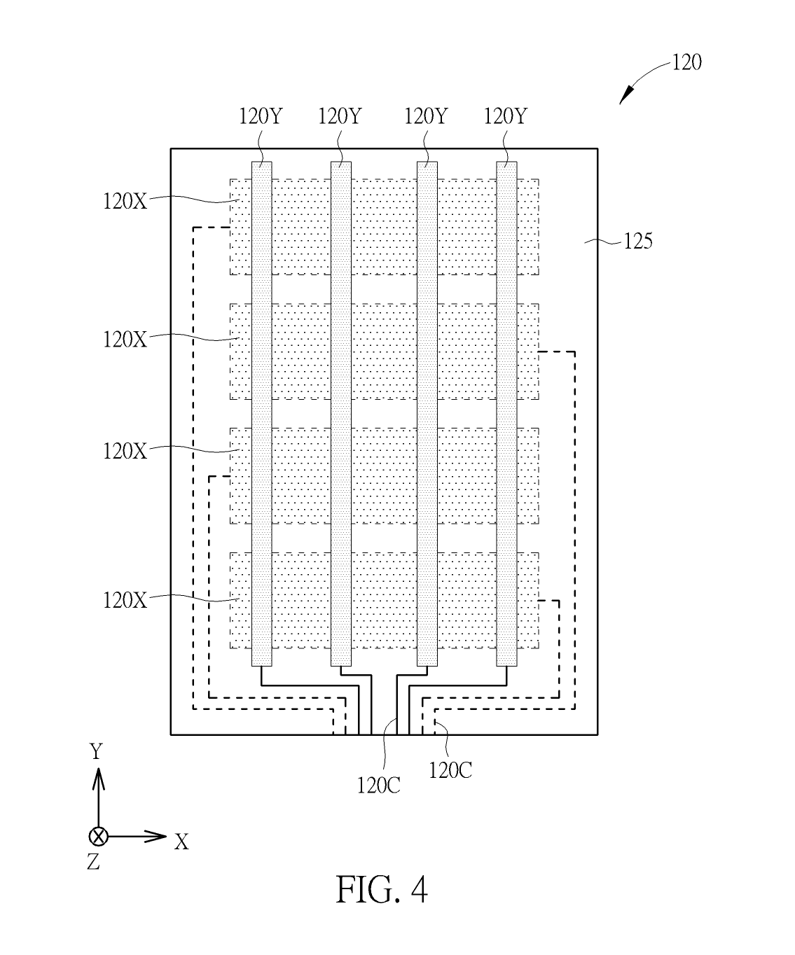

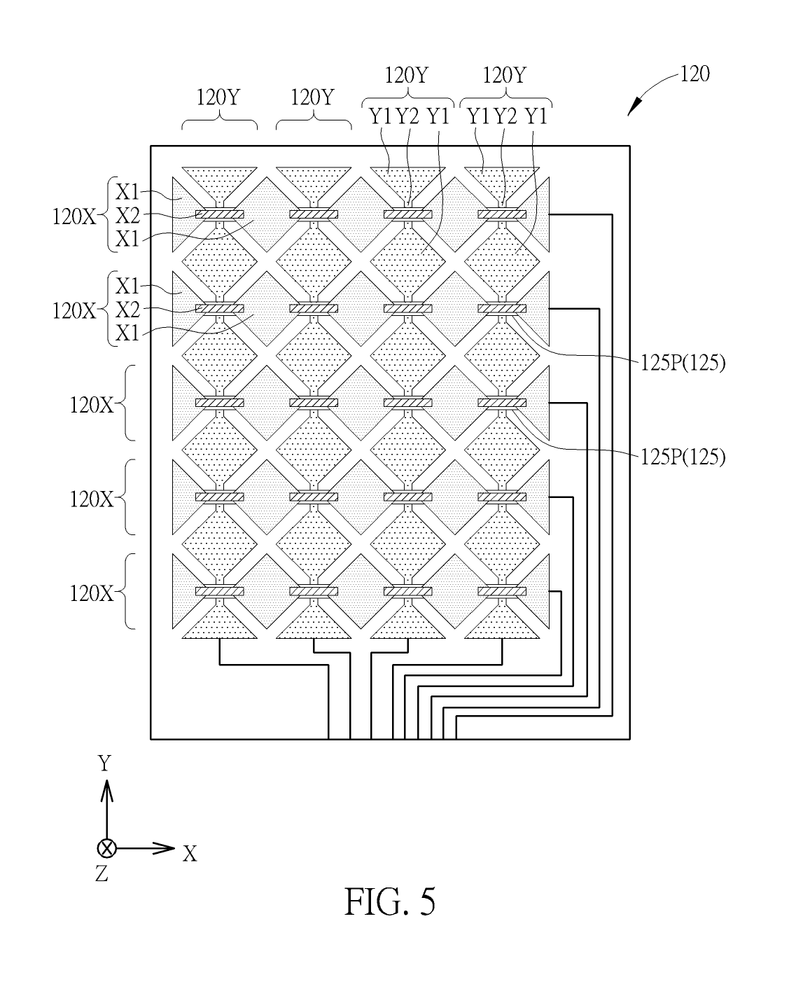

Please refer to FIGS. 1-5 for further descriptions of the first touch sensing unit 120. FIG. 2, FIG. 3 FIG. 4 and FIG. 5 are schematic diagrams illustrating different types of the first touch sensing unit in this embodiment. As shown in FIG. 2, the first touch sensing unit 120 in this embodiment may include a plurality of touch electrodes 120S and a plurality of traces 120C. Each of the traces 120C is electrically connected to a corresponding touch electrode 120S. The touch electrodes 120S are disposed to be electrically isolated from one another so as to perform a self-capacitance touch sensing operation, but not limited thereto. The shape of each touch electrode 120S may be a rectangle, a rhombus, a triangle or other appropriate geometrical patterns. Additionally, as shown in FIG. 3, the touch electrodes 120S may include at least one touch signal driving electrode 120T and at least one touch signal receiving electrode 120R disposed to be separated from each other so as to perform a mutual-capacitance touch sensing operation, but not limited thereto.

As shown in FIG. 4, the first touch sensing unit 120 may also include a plurality of first axis electrodes 120X and a plurality of second axis electrodes 120Y. Each of the first axis electrodes 120X extends along a first direction X, and each of the second axis electrodes 120Y extends along a second direction Y. The first axis electrodes 120X at least partially overlap the second axis electrodes 120Y along a vertical projective direction Z perpendicular to the thin substrate 110. The first axis electrodes 120X are electrically isolated from the second axis electrodes 120Y. The first direction X is substantially perpendicular to the second direction Y, but not limited thereto. The first axis electrode 120X and the second axis electrode 120Y may be a touch signal driving electrode or a touch signal receiving electrode respectively so as to perform a mutual-capacitance touch sensing operation, but not limited thereto. As shown in FIG. 1 and FIG. 4, the touch device 100 may further include an insulation layer 125 disposed between the first axis electrode 120X and the second axis electrode 120Y so as to electrically isolate the first axis electrodes 120X from the second axis electrodes 120Y. The insulation layer 125 may include an organic insulation material or an inorganic insulation material. In this embodiment, a width of at least one of the first axis electrodes 120X is wider than or equal to a width of each second axis electrode 120Y, but the present invention is not limited to this. In other embodiments of the present invention, a width of at least one of the second axis electrodes 120Y may also be wider than or equal to a width of each first axis electrode 120X. For example, when the first axis electrode 120X is a touch signal driving electrode and the second axis electrode 120Y is a touch signal receiving electrode, the width of each first axis electrode 120X is wider than or equal to the width of each second axis electrode 120Y. Comparatively, when the second axis electrode 120Y is a touch signal driving electrode and the first axis electrode 120X is a touch signal receiving electrode, the width of each second axis electrode 120Y is wider than or equal to the width of each first axis electrode 120X.

As shown in FIG. 5, each of the first axis electrodes 120X may include a plurality of first sub-electrodes X1 and at least one first connecting line X2 disposed between two adjacent first sub-electrodes X1, and the first connecting line X2 is configured to electrically connect the two adjacent first sub-electrodes X1. Each of the second axis electrodes 120Y may include a plurality of second sub-electrodes Y1 and at least one second connecting line Y2 disposed between two adjacent second sub-electrodes Y1, and the second connecting line Y2 is configured to electrically connect the two adjacent second sub-electrodes Y1. As shown in FIG. 1 and FIG. 5, the touch device 100 may further include at least one insulation block 125P disposed between the first connecting line X2 and the second connecting line Y2 so as to electrically isolate the first axis electrodes 120X from the second axis electrodes 120Y, but not limited thereto. It is worth noting that the touch electrode 120S, the trace 120C, the first axis electrode 120X, the second axis electrode 120Y, the first sub-electrode X1, the first connecting line X2, the second sub-electrode Y1 and the second connecting line Y2 mentioned above may preferably be made of transparent materials, such as indium tin oxide (ITO), indium zinc oxide (IZO) and aluminum zinc oxide (AZO), metal materials or other appropriate conductive materials respectively. The metal materials mentioned above may include at least one of aluminum, copper, silver, chromium, titanium and molybdenum, a composite layer of the materials mentioned above, or an alloy of the materials mentioned above, but not limited thereto. The metal materials may present in a mesh configuration, for instance, a metal mesh. The conductive materials mentioned above may include conductive particles, carbon nanotubes or silver nanowires, but not limited thereto. The conductive materials may also present in a mesh configuration, for instance, a conductive mesh. Additionally, the first touch sensing unit 120 of the present invention is not limited to the different types shown in FIGS. 2-5. The first touch sensing unit 120 shown in FIGS. 2-5 may also be applied to other embodiments of the present invention described below.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

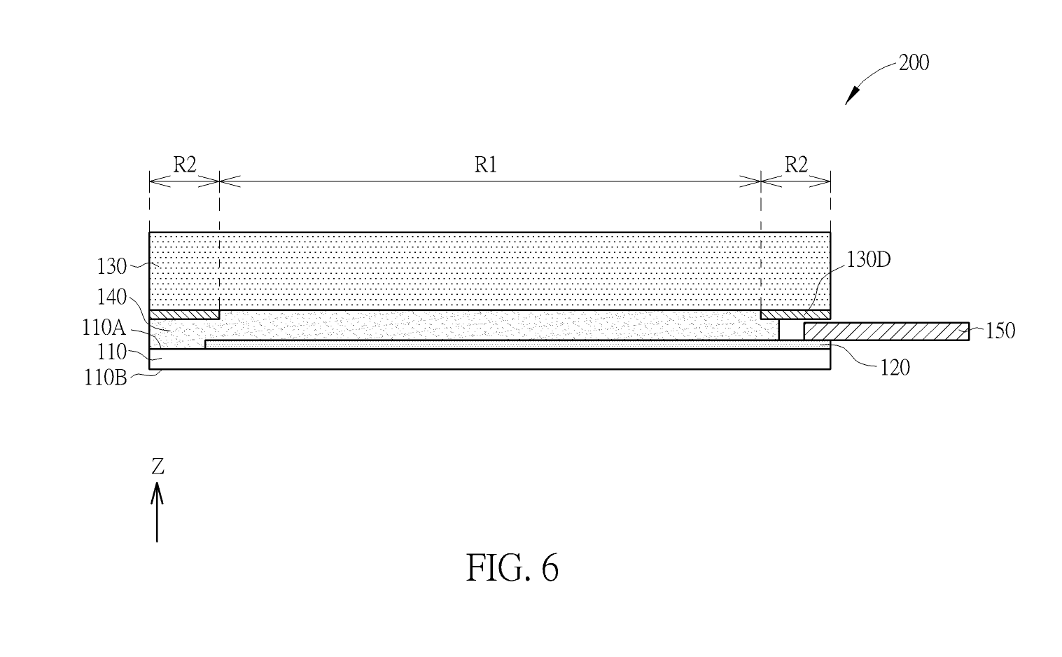

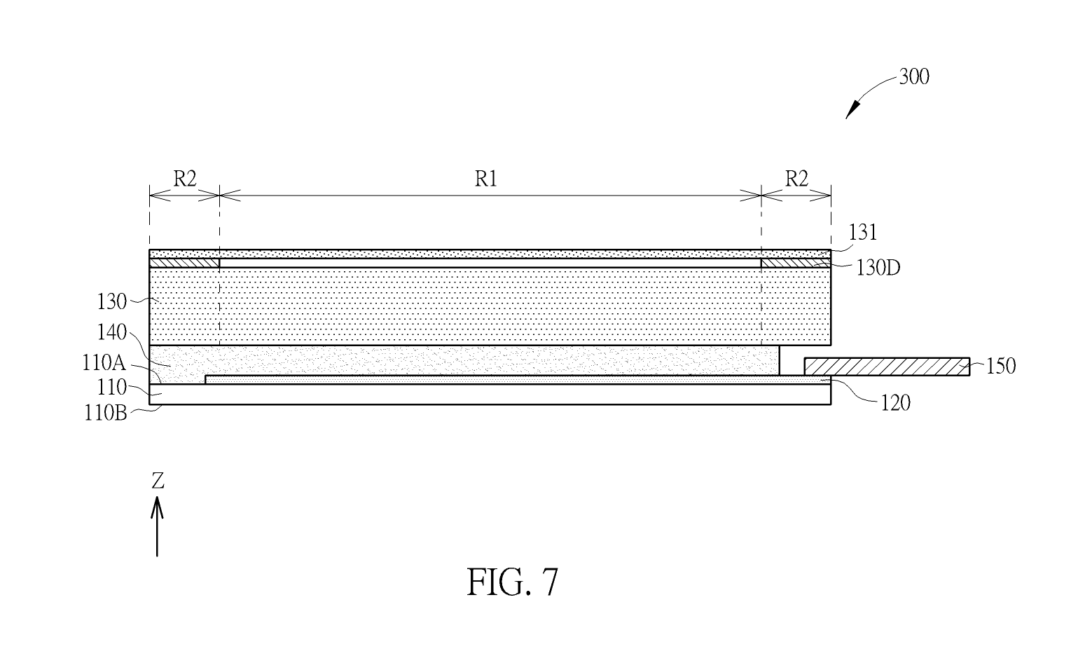

FIG. 6 is a schematic diagram illustrating a touch device 200 according to a second embodiment of the present invention. As shown in FIG. 6, the difference between the touch device 200 and the touch device in the first embodiment is that the touch device 200 further includes a decoration layer 130D disposed on the cover substrate 130. The cover substrate 130 has a light-permeable region R1 and a peripheral region R2 disposed on at least one side of the light-permeable region R1, and the decoration layer 130D is disposed in the peripheral region R2 so as to present a decoration effect on a surface of the cover substrate 130 opposite to the decoration layer 130D, but the present invention is not limited to this. For example, please refer to FIG. 7. FIG. 7 is a schematic diagram illustrating a touch device 300 according to a third embodiment of the present invention. As shown in FIG. 7, the touch device 300 may further include a supporting substrate 131 and a decoration layer 130D. The supporting substrate 131 is disposed on the cover substrate 130. The decoration layer 130D is disposed on the supporting substrate 131, and the decoration layer 130D is disposed correspondingly to the peripheral region R2. The decoration layer 130D may be formed on the supporting substrate 131 before the supporting substrate 131 is attached to the cover substrate 130. The decoration layer 130D may be a black decoration layer or a color decoration layer. The decoration layer 130D may be made of a photoresist material, a diamond-like material, a ceramic material or an ink material. The decoration layer 130D may be a single layer structure or a multi-layered structure. For example, when the decoration layer 130D is a color decoration layer, the decoration layer 130D may be a single layer structure or a multi-layered structure made of color inks or photoresist. A shielding layer (not shown) or an anti-reflection layer (not shown) may be optionally disposed on the color inks or the color photoresist so as to increase the optical density of the decoration layer 130D. The material of the shielding layer is not limited to inks. Translucent materials, low light-permeable materials, or light-impermeable materials capable of eliminating light leakage may be used to form the shielding layer. For example, the shielding layer may be made of a photoresist material, a diamond-like material or a ceramic material. In addition, the shielding layer may also be made of an infrared permeable material. In other words, the decoration layer 130D may be a single layer structure or a multiple layered structure of photoresist materials, diamond-like materials, ceramic materials, ink materials or other appropriate black or non-black decoration materials.

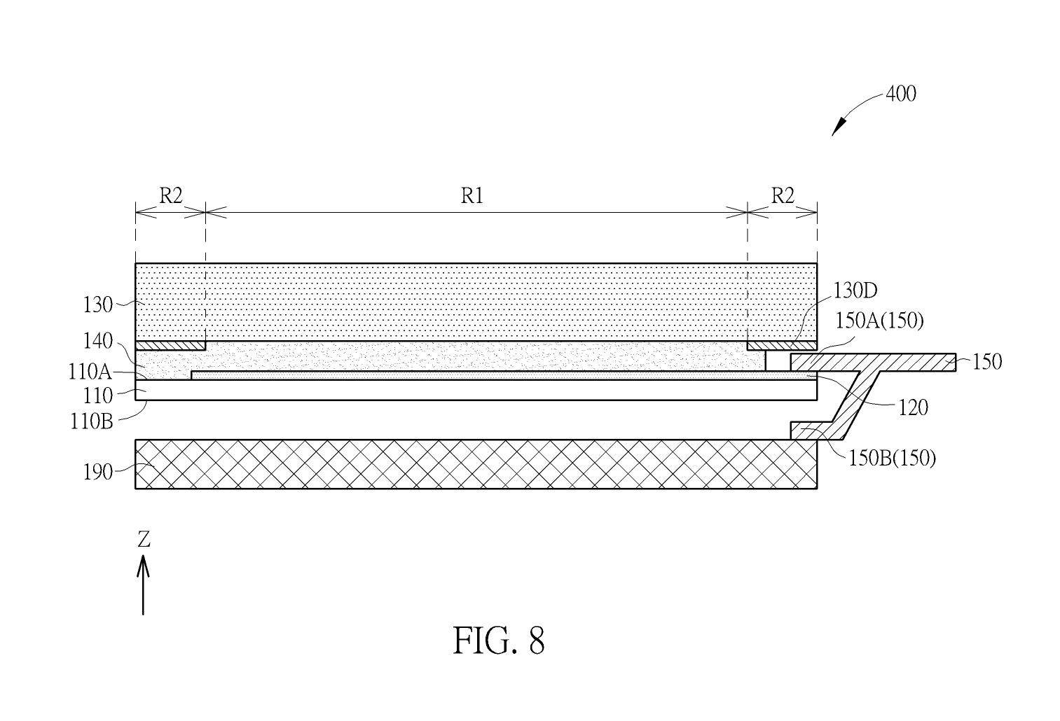

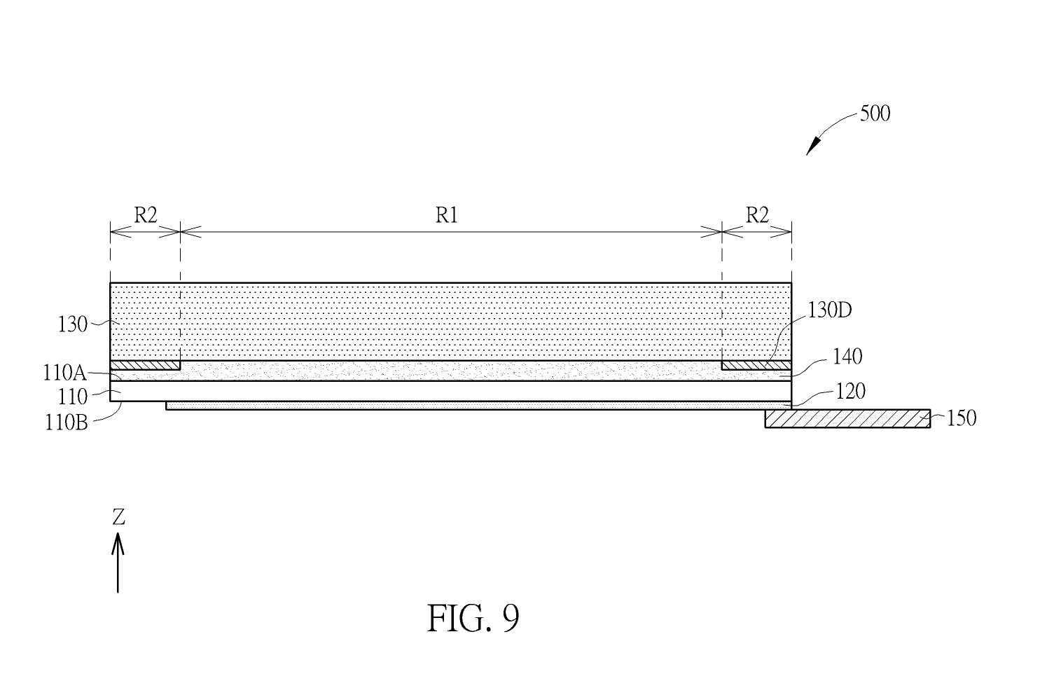

FIG. 8 is a schematic diagram illustrating a touch device 400 according to a fourth embodiment of the present invention. As shown in FIG. 8, the difference between the touch device 400 and the touch device in the second embodiment is that the touch device 400 further includes a display device 190 disposed on a side of the second surface 110B of the thin substrate 110. Additionally, the first outer unit 150 in this embodiment may include a first connection end 150A and a second connection end 150B. The first connection end 150A is disposed on the first surface 110A of the thin substrate 110 so as to be electrically connected to the first touch sensing unit 120. The second connection end 150B is electrically connected to the display device 190. In other words, the display device 190 and the first touch sensing unit 120 in this embodiment may be electrically connected to the same first outer unit 150 so as to be integrated structurally, but not limited thereto. The display device 190 may include a liquid crystal display device, an organic light emitting diode (OLED) display device, an electro-wetting display device, an e-ink display device, a plasma display device, a field emission display (FED) device or other appropriate display devices. The touch device 400 in this embodiment may be regarded as an out-cell type touch display device accordingly.

FIG. 9 is a schematic diagram illustrating a touch device 500 according to a fifth embodiment of the present invention. As shown in FIG. 9, the difference between the touch device 500 and the touch device in the second embodiment is that, in the touch device 500, the first touch sensing unit 120 and at least a part of the first outer unit 150 are disposed on a side of the second surface 110B of the thin substrate 110. Because the first outer unit 150 and the first adhesive layer 140 in this embodiment are disposed on different sides of the thin substrate 110 respectively, the thickness of the first adhesive layer 140 may not be constrained by the first outer unit 150. The thickness of the first adhesive layer 140 may be reduced to decrease the total thickness of the touch device 500, and the touch device 500 may become thinner accordingly. In other words, the thickness of the first adhesive layer 140 may be thinner than the thickness of the first outer unit 150 preferably, but not limited thereto.

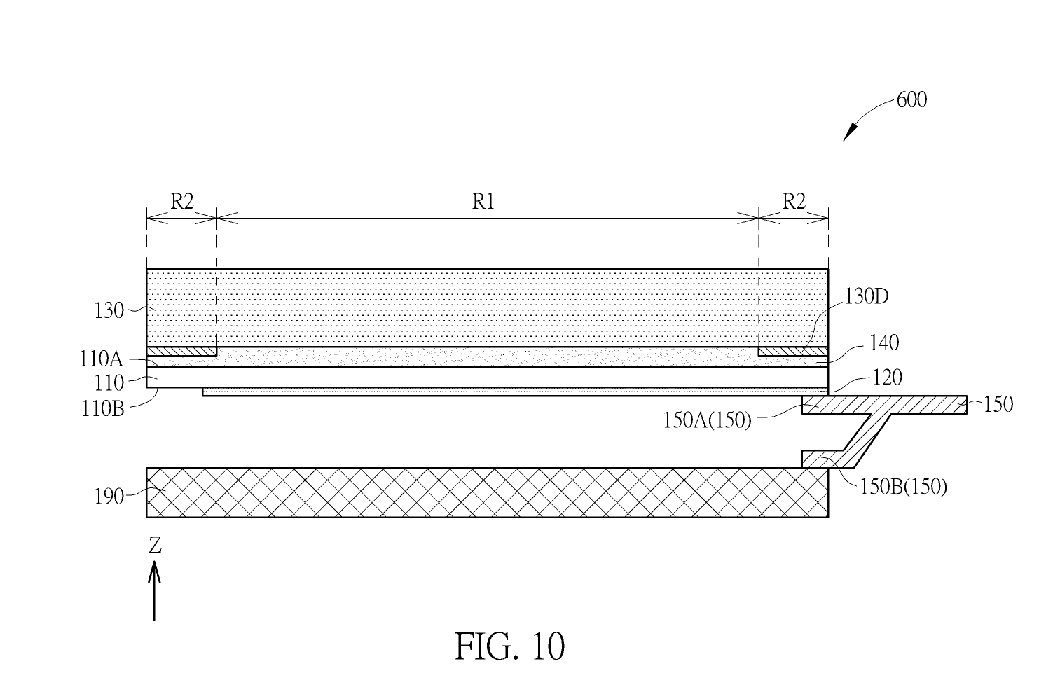

FIG. 10 is a schematic diagram illustrating a touch device 600 according to a sixth embodiment of the present invention. As shown in FIG. 10, the difference between the touch device 600 and the touch device in the fifth embodiment is that the touch device 600 further includes the display device 190 disposed on a side of the second surface 110B of the thin substrate 110. Additionally, the first outer unit 150 in this embodiment may include a first connection end 150A and a second connection end 150B. The first connection end 150A is disposed on the second surface 110B of the thin substrate 110 so as to be electrically connected to the first touch sensing unit 120. The second connection end 150B is electrically connected to the display device 190. In other words, the display device 190 and the first touch sensing unit 120 in this embodiment may be electrically connected to the same first outer unit 150 so as to be integrated structurally, but not limited thereto.

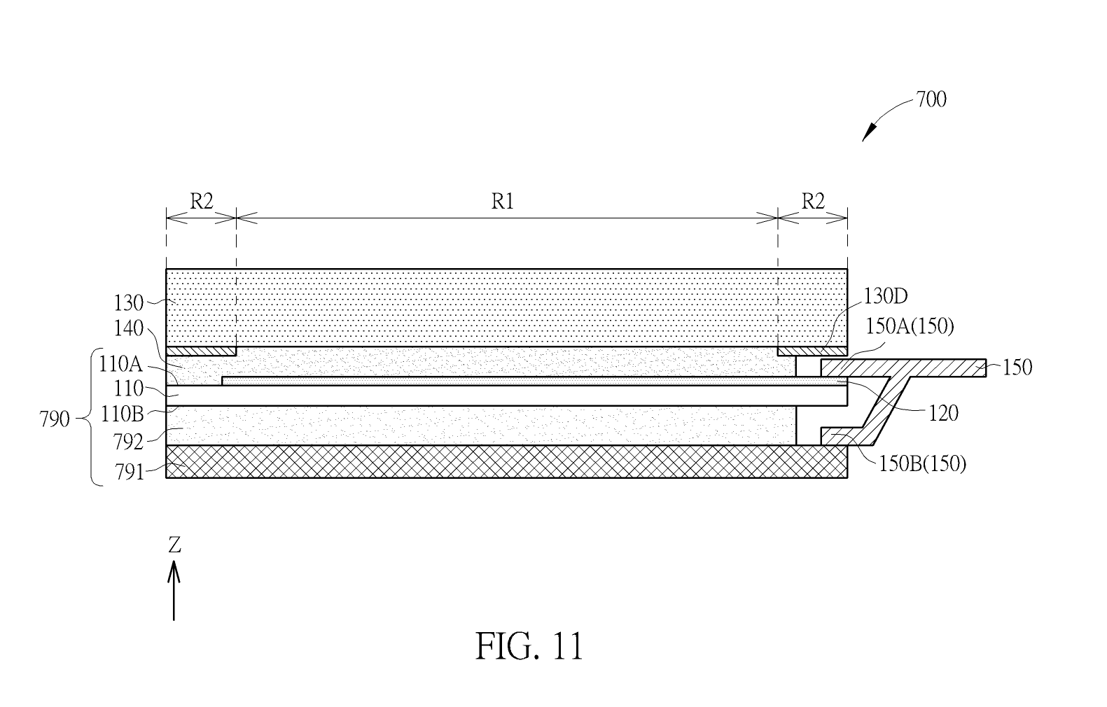

FIG. 11 is a schematic diagram illustrating a touch device 700 according to a seventh embodiment of the present invention. As shown in FIG. 11, the difference between the touch device 700 and the touch device in the fourth embodiment is that the thin substrate 110 in this embodiment includes a substrate of a display device. The substrate of the display device may include a color filter substrate, an array substrate, an encapsulating substrate of an organic light emitting display device or other substrates used in display devices. A display lower substrate 791, a display medium 792 and the thin substrate 110 of this embodiment may be used to form a display device 790. The display lower substrate 791 and the display medium 792 are disposed on a side of the second surface 110B of the thin substrate 110. In other words, the first touch sensing unit 120 in this embodiment is disposed on the thin substrate 110 of the display device 790, and the touch device 700 may be regarded as an on-cell type touch display device, but not limited thereto. It is worth noting that the second connection end 150B of the first outer unit 150 in this embodiment may be disposed on the display lower substrate 791 so as to be electrically connected to a driving unit, such as a thin film transistor array, in the display device 790, but not limited thereto. The display medium 792 is disposed between the thin substrate 110 and the display lower substrate 791. According to different types of the display devices, the display medium 792 may include a liquid crystal material, an organic light emitting material, an electro-wetting display material, an e-ink material, a plasma material or other materials for generating display effects.

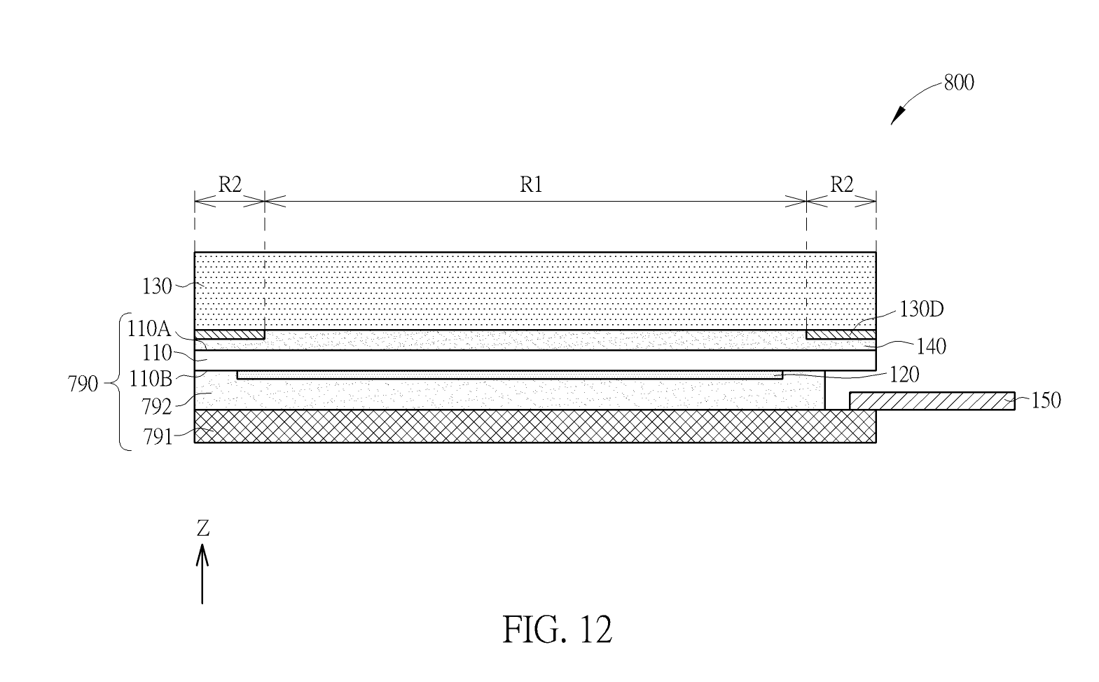

FIG. 12 is a schematic diagram illustrating a touch device 800 according to an eighth embodiment of the present invention. As shown in FIG. 12, the difference between the touch device 800 and the touch device in the seventh embodiment is that the first touch sensing unit 120 in this embodiment is disposed on the second surface 110B of the thin substrate 110. The first outer unit 150 is at least partially disposed on the display lower substrate 791 preferably. The first outer unit 150 may be electrically connected to the first touch sensing unit 120 disposed on the thin substrate 110 via a conductive unit (not shown), such as Au balls, an anisotropic conductive film (ACF) or a silver paste, disposed between the thin substrate 110 and the display lower substrate 791, but not limited thereto. The touch device 800 in this embodiment may be regarded as an in-cell type touch display device accordingly. The touch device 800 may further become thinner because the thin substrate 110 and the first touch sensing unit 120 are disposed by an in-cell approach.

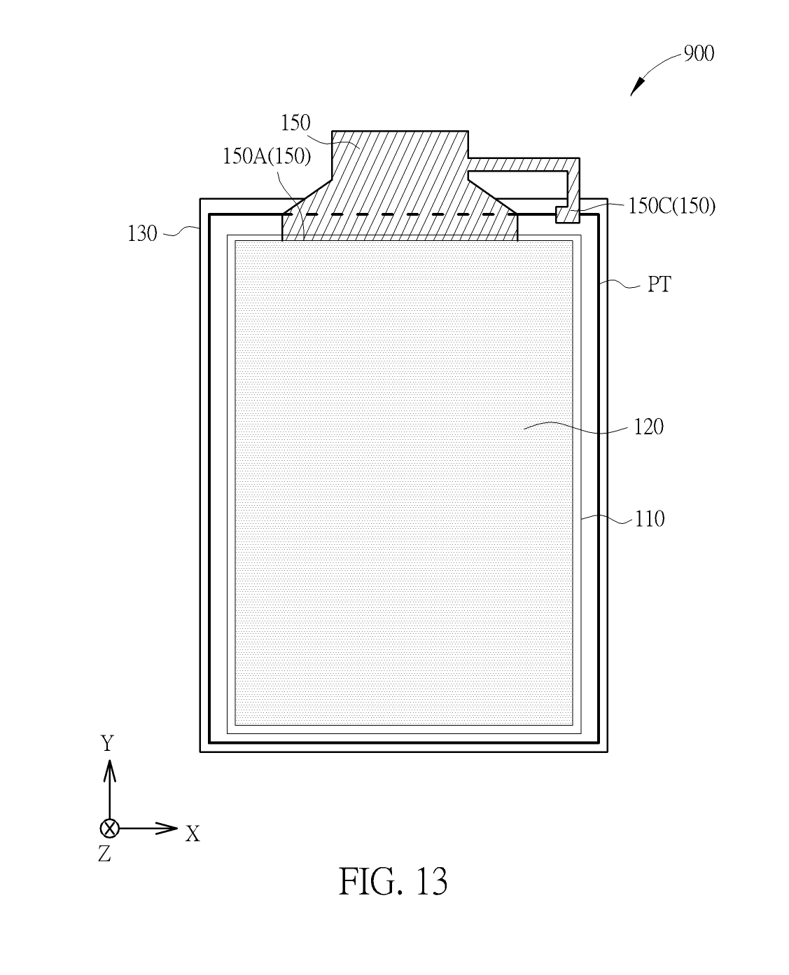

FIG. 13 is a schematic diagram illustrating a touch device 900 according to a ninth embodiment of the present invention. As shown in FIG. 13, the difference between the touch device 900 and the touch device in the first embodiment is that the touch device 900 further includes a conductive protection line PT disposed on the cover substrate 130. The conductive protection line PT may be a ground wire, an electrically floating line or a line electrically coupled to a voltage source. The conductive protection line PT may surround the first touch sensing unit 120 preferably so as to generate a protection effect, but not limited thereto. Additionally, the first outer unit 150 in this embodiment may further include a third connection end 150C disposed on the cover substrate 130. The first outer unit 150 is electrically connected to the conductive protection line PT via the third connection end 150C. In other words, the first outer unit 150 may be shared by the first touch sensing unit 120 disposed on the thin substrate 110 and the conductive protection line PT disposed on the cover substrate 130 so as to simplify the structure of the touch device 900, but not limited thereto. It is worth noting that the conductive protection line PT and the allocation of the third connection end 150C of the first outer unit 150 in this embodiment may also be applied to other embodiment of the present invention.

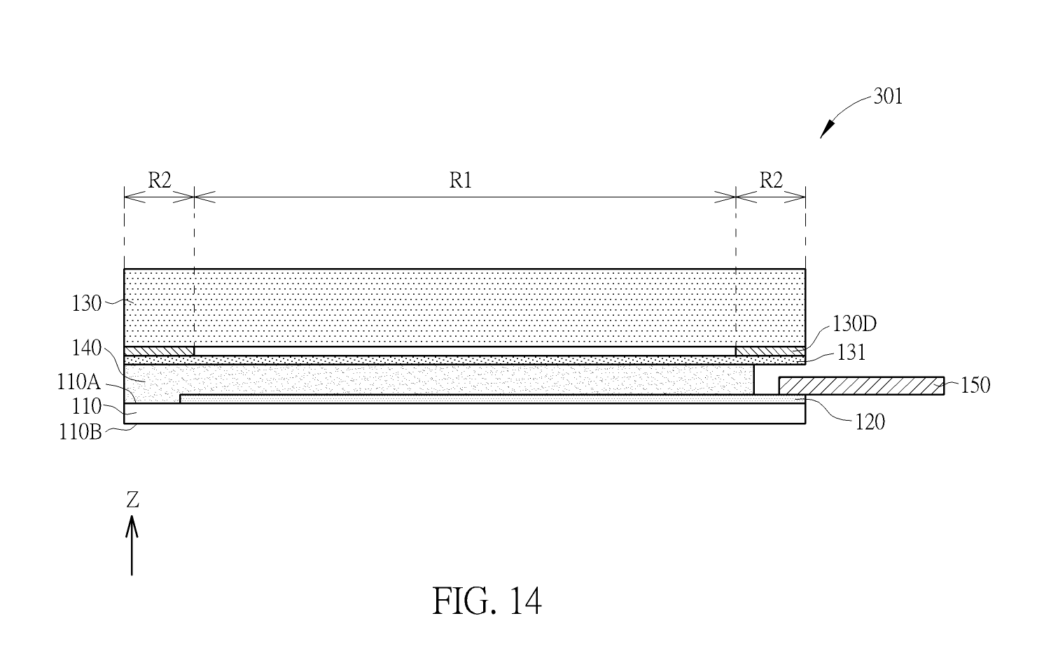

FIG. 14 is a schematic diagram illustrating a touch device 301 according to a tenth embodiment of the present invention. As shown in FIG. 14, the difference between the touch device 301 and the touch device in the third embodiment is that the supporting substrate 131 in this embodiment is disposed on a side of the cover substrate 130 facing the thin substrate 110. The decoration layer 130D is disposed on the supporting substrate 131, the decoration layer 130D is disposed correspondingly to the peripheral region R2, and the decoration layer 130D is disposed between the supporting substrate 131 and the cover substrate 130 preferably, but not limited thereto.

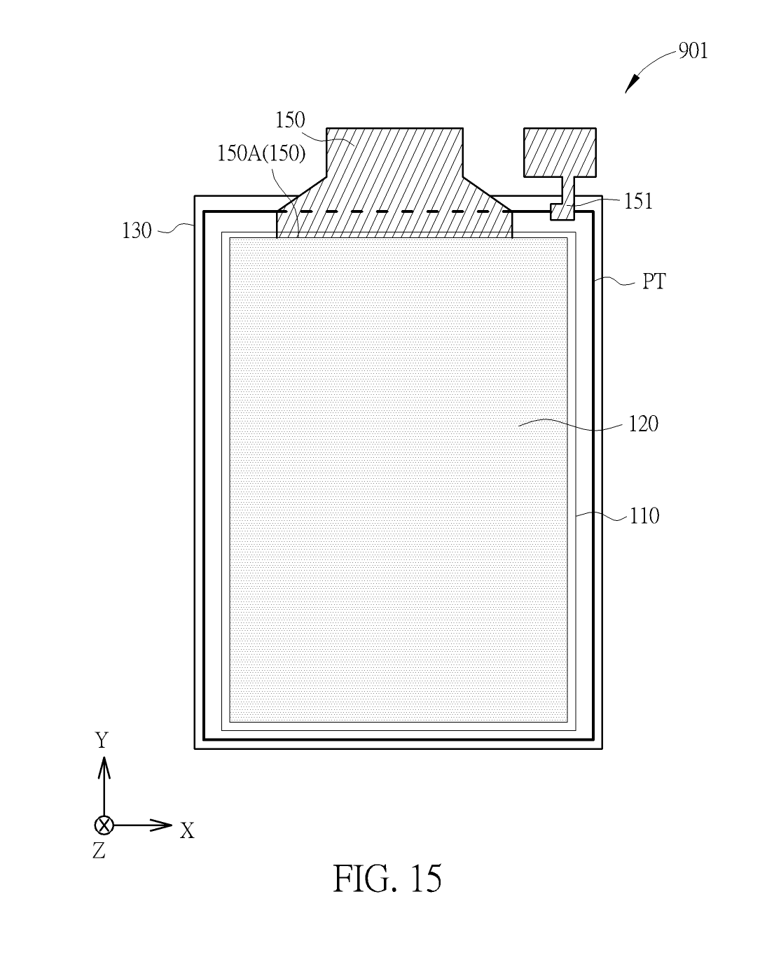

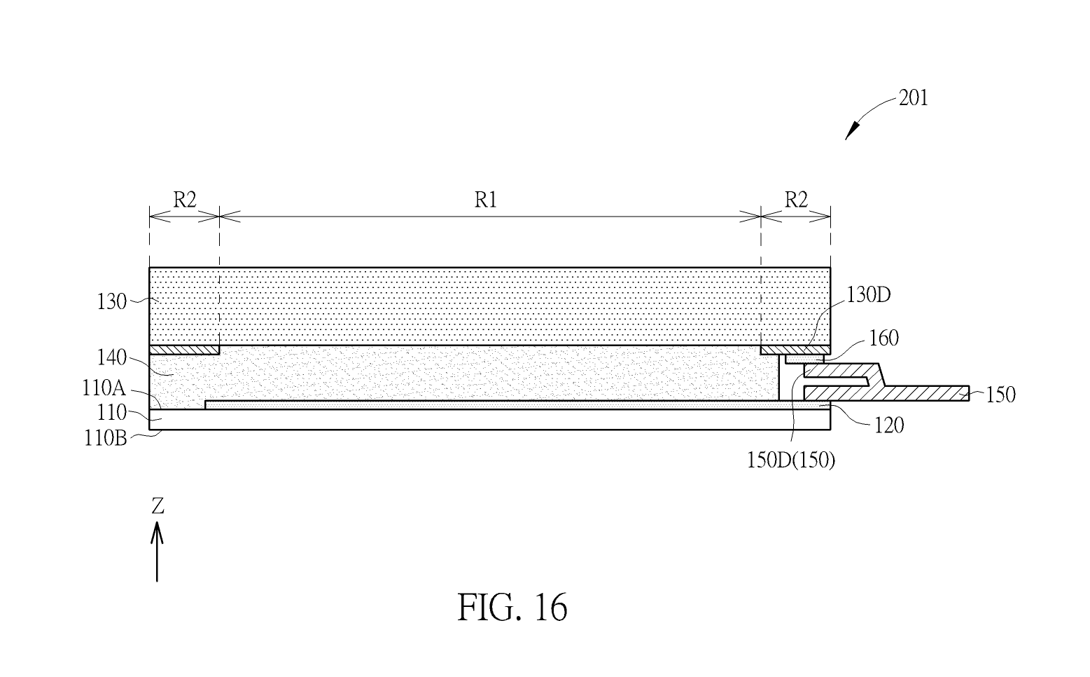

FIG. 15 is a schematic diagram illustrating a touch device 901 according to an eleventh embodiment of the present invention. As shown in FIG. 15, the difference between the touch device 901 and the touch device in the ninth embodiment is that the touch device 901 further includes a second outer unit 151. The second outer unit 151 is electrically connected to the conductive protection line PT. In other words, signals may be transmitted to and/or from the first touch sensing unit 120 disposed on the thin substrate 110 and the conductive protection line PT disposed on the cover substrate 130 respectively via different outer units. The second outer unit 151 may include a flexible printed circuit, an integrated circuit or other outer unit electrically connected to the conductive protection line PT.

FIG. 16 is a schematic diagram illustrating a touch device 201 according to a twelfth embodiment of the present invention. As shown in FIG. 16, the difference between the touch device 201 and the touch device in the second embodiment is that the touch device 201 further includes a second touch sensing unit 160 disposed on the cover substrate 130. The second touch sensing unit 160 may be disposed on the peripheral region R2 of the cover substrate 130 so as to perform a hovering touch operation, or according to function requirement of the touch device 201, the second touch sensing unit 160 may also be disposed correspondingly to specific patterns or letter areas in the decoration layer 130D within the peripheral region R2 so as to perform touch effects corresponding to the patterns and the letters, but not limited thereto. Additionally, the first outer unit 150 in this embodiment may further include a fourth connection end 150D disposed on the cover substrate 130, and the first outer unit 150 is electrically connected to the second touch sensing unit 160 via the fourth connection end 150D. In other words, the first outer unit 150 may be shared by the first touch sensing unit 120 disposed on the thin substrate 110 and the second touch sensing unit 160 disposed on the cover substrate 130 so as to simplify the structure of the touch device 201, but not limited thereto. It is worth noting that the second touch sensing unit 160 and the allocation of the fourth connection end 150D of the first outer unit 150 in this embodiment may also be applied to other embodiment of the present invention.

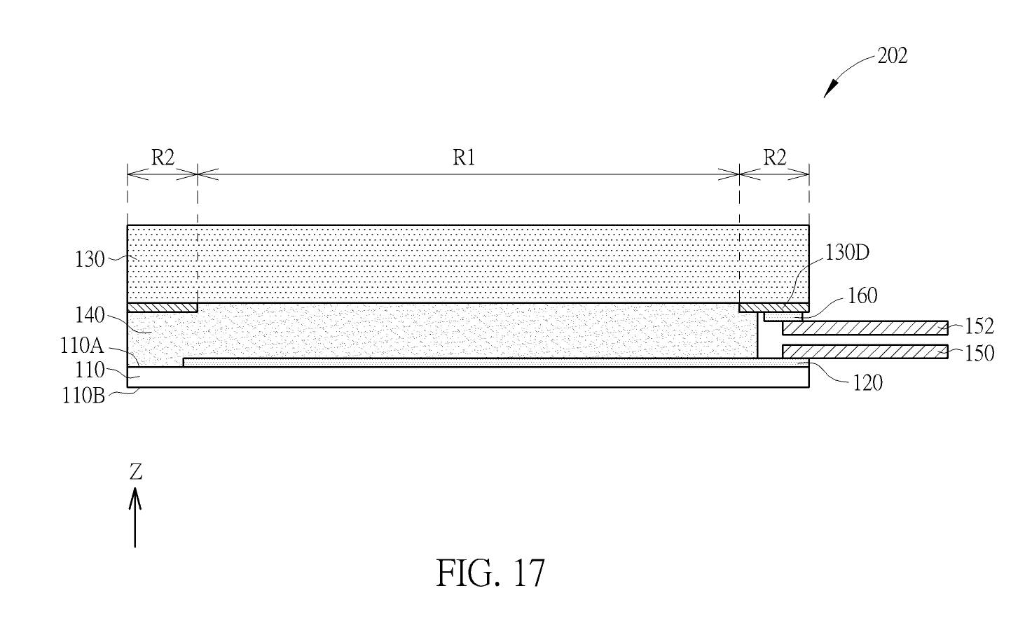

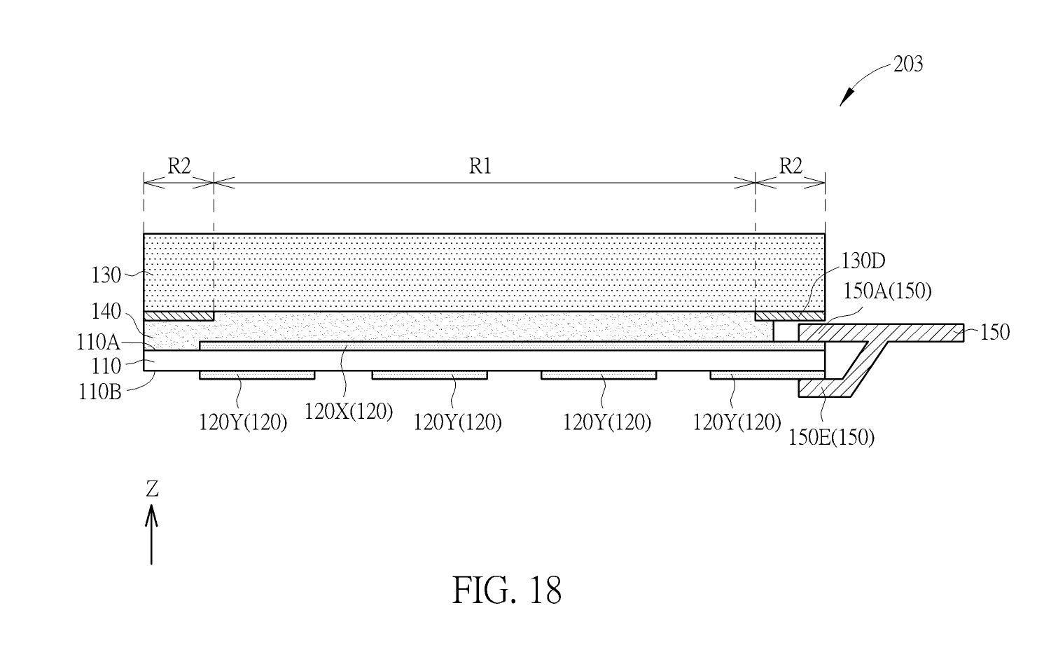

FIG. 17 is a schematic diagram illustrating a touch device 202 according to a thirteen embodiment of the present invention. As shown in FIG. 17, the difference between the touch device 202 and the touch device in the thirteenth embodiment is that the touch device 202 further includes a third outer unit 152. The third outer unit 152 is electrically connected to the second touch sensing unit 160. The third outer unit 152 may include a flexible printed circuit, an integrated circuit or other outer unit electrically connected to the second touch sensing unit 160. In other words, signals may be transmitted to and/or from the first touch sensing unit 120 disposed on the thin substrate 110 and the second touch sensing unit 160 disposed on the cover substrate 130 respectively via different outer units.

FIG. 18 is a schematic diagram illustrating a touch device 203 according to a fourteenth embodiment of the present invention. As shown in FIG. 18, the difference between the touch device 203 and the touch device in the first embodiment is that the first axis electrodes 120X are disposed on the first surface 110A of the thin substrate 110, and the second axis electrodes 120Y in this embodiment are disposed on the second surface 110B of the thin substrate 110. In other words, the second axis electrode 120Y and the first axis electrode 120X are disposed on different two sides of the thin substrate 110. The first axis electrode 120X and the second axis electrode 120Y may be a touch signal driving electrode or a touch signal receiving electrode respectively so as to perform a mutual-capacitance touch sensing operation, but not limited thereto. Additionally, the first outer unit 150 in this embodiment may include a first connection end 150A and a fifth connection end 150E. The first connection end 150A is disposed on the first surface 110A of the thin substrate 110 so as to be electrically connected to the first axis electrodes 120X, and the fifth connection end 150E is disposed on the second surface 110B of the thin substrate 110 so as to be electrically connected to the second axis electrodes 120Y. It is worth noting that, in this embodiment, the second axis electrodes 120Y are touch signal driving electrodes preferably, and the first axis electrodes 120X are touch signal receiving electrodes preferably. The width of each second axis electrode 120Y is wider than or equal to the width of each first axis electrode 120X preferably. In other words, a covering area of the second axis electrodes 120Y on the thin substrate 110 is larger than or equal to a covering area of the first axis electrodes 120X on the thin substrate 110 preferably. In addition, the second axis electrodes 120Y in this embodiment may also be an interference shielding layer configured to isolate the touch device from interference of other outer signals, but not limited thereto.

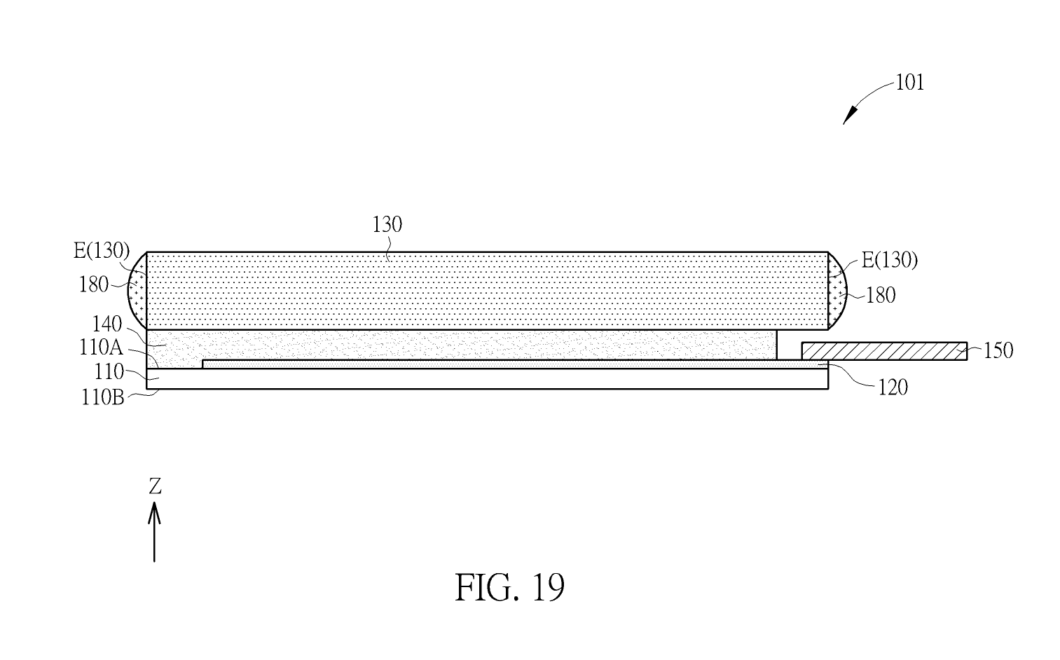

FIG. 19 is a schematic diagram illustrating a touch device 101 according to a fifteenth embodiment of the present invention. As shown in FIG. 19, the difference between the touch device 101 and the touch device in the first embodiment is that the touch device 101 further includes a protection layer 180 disposed on at least one peripheral side E of the cover substrate 130. The protection layer 180 may be disposed on the surrounding peripheral side of the cover substrate 130 so as to form a required protection effect, but the present invention is not limited to this. In other words, the protection layer 180 may surround all of the peripheral side of the cover substrate 130 or be disposed on a part of the peripheral side E. The protection layer 180 may be formed by dispensing, spray coating, immersing or other appropriate processes. The protection layer 180 may include a protection coating layer or a protection coating glue, but not limited thereto. The protection layer 180 in this embodiment may also be selectively disposed in the embodiments described above according to other design considerations. For example, the protection layer 180 may be disposed corresponding to the decoration layer in the embodiments mentioned above, and the protection layer 180 may partially overlap the decoration layer, but not limited thereto.

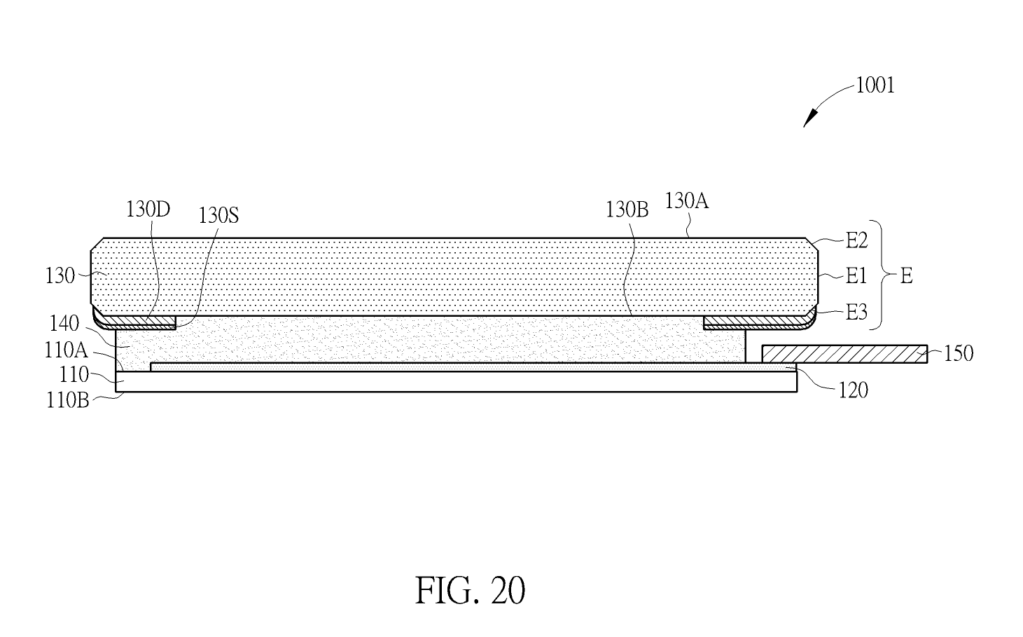

FIG. 20 is a schematic diagram illustrating a touch device 1001 according to a sixteenth embodiment of the present invention. As shown in FIG. 20, the difference between the touch device 1001 and the touch device in the second embodiment is that the cover substrate 130 in this embodiment has a peripheral side E, a third surface 130A and a fourth surface 130B opposite to the third surface 130A. The fourth surface 130B faces the thin substrate 110, and the decoration layer 130D at least partially covers the fourth surface 130B. In this embodiment, the decoration layer 130D may further partially cover the peripheral side E, but not limited thereto. Specifically, the peripheral side E of the cover substrate 130 in this embodiment may be composed of a first flat surface E1, a first oblique surface E2 and a second oblique surface E3. The first oblique surface E2 is connected to the third surface 130A, the second oblique surface E3 is connected to the fourth surface 130B, and the first flat surface E1 is disposed between the first oblique surface E2 and the second oblique surface E3. The condition of the peripheral side E in this embodiment may be regarded as a so-called “C angle”, but not limited thereto. In this embodiment, the decoration layer 130D may partially cover the second oblique surface E3 so as to ensure the decoration effect on the edge of the cover substrate 130, but not limited thereto. Additionally, the touch device 1001 may further include a light-shielding layer 130S disposed on the decoration layer 130D. The shielding layer 130S may include a dark ink layer, a color photoresist layer or a reflection layer so as to be collocated with the decoration layer 130D for generating the required decoration effects. The reflection layer mentioned above may include an ink mirror, a metal material or other appropriate reflective materials. It is worth noting that the light-shielding layer in this embodiment may also be applied to other embodiments mentioned above or being described below according to other design considerations.

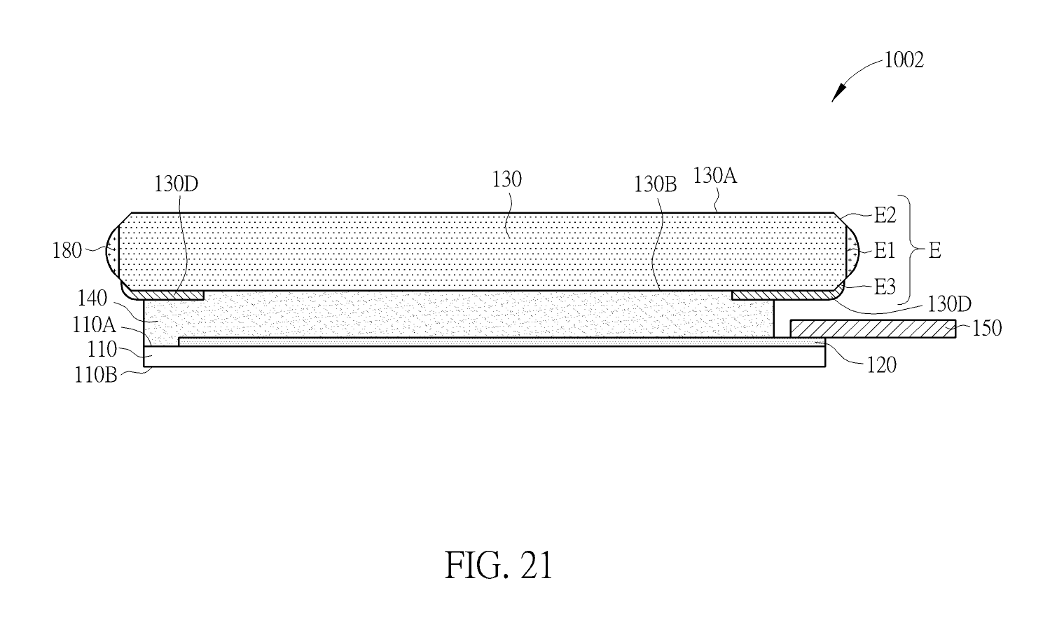

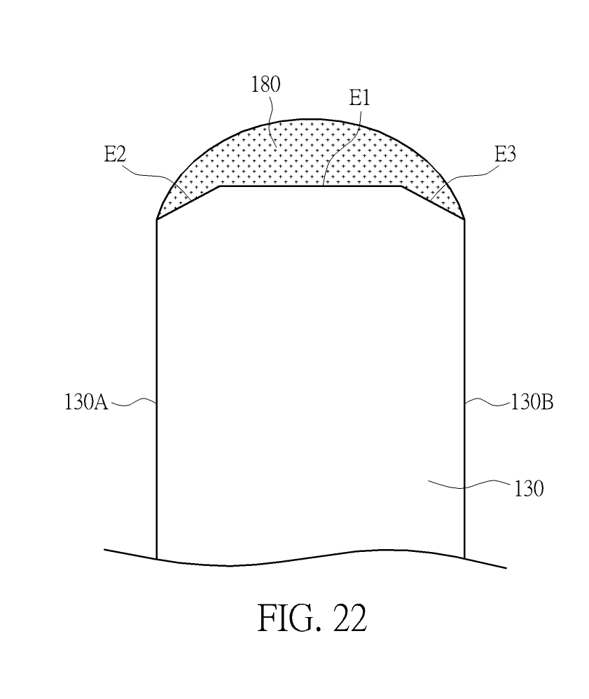

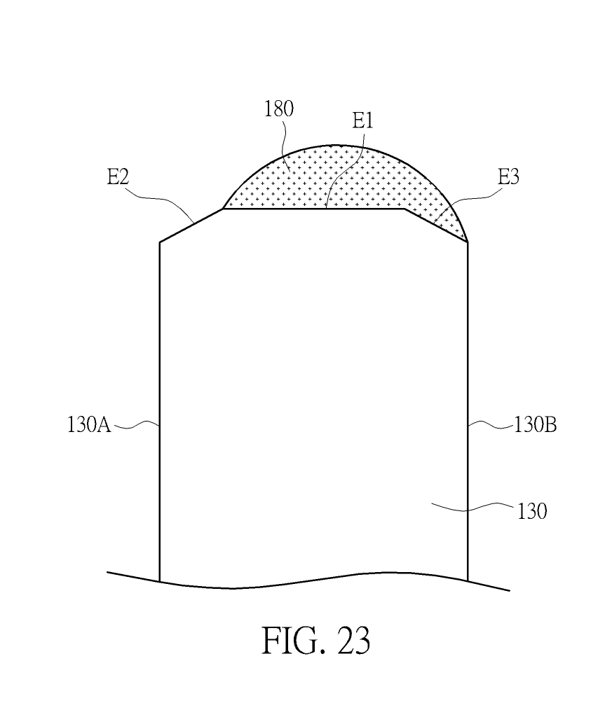

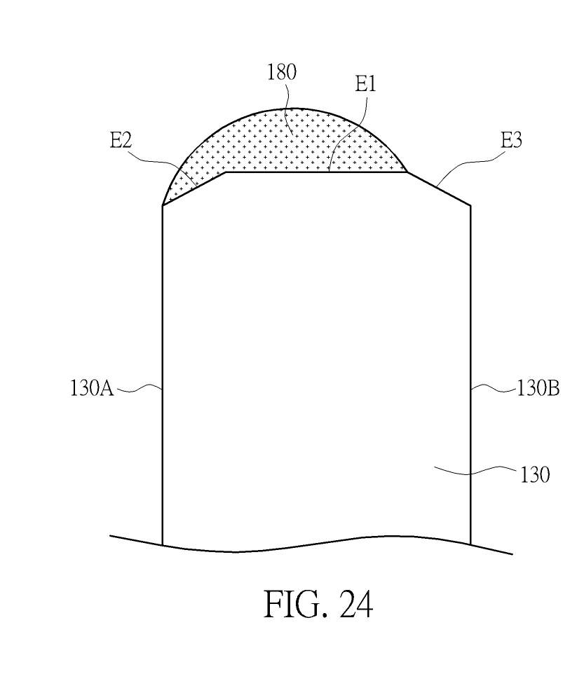

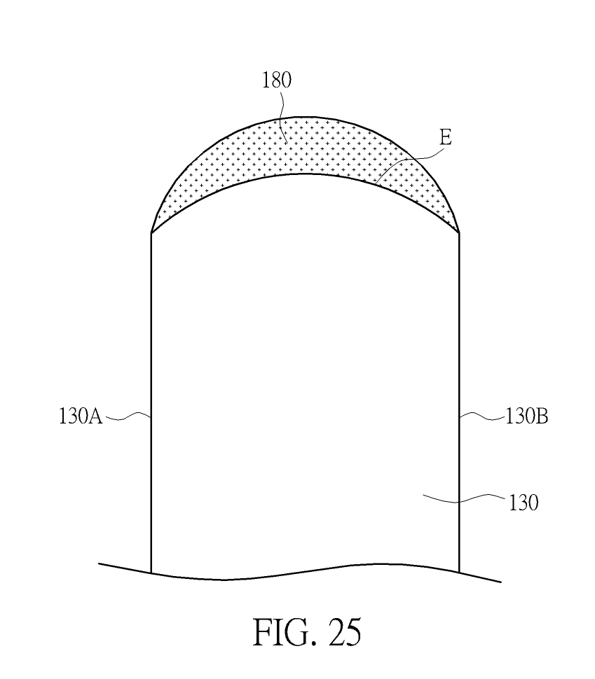

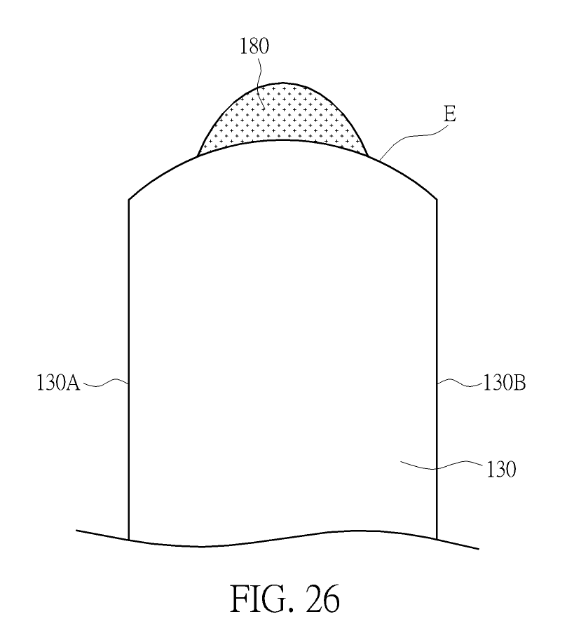

FIG. 21 is a schematic diagram illustrating a touch device 1002 according to a seventeenth embodiment of the present invention. FIG. 22, FIG. 23, FIG. 24, FIG. 25, FIG. 26, FIG. 27 and FIG. 28 are schematic diagrams illustrating allocation conditions of a cover substrate and a protection layer according to the seventeenth embodiment of the present invention. As shown in FIG. 21, the difference between the touch device 1002 and the touch device in the sixteenth embodiment is that the touch device 1002 further includes a protection layer 180 disposed on the peripheral side E of the cover substrate 130, and the protection layer 180 at least partially covers the first flat surface E1, the first oblique surface E2 or/and the second oblique surface E3. Specifically, as shown in FIG. 21, the protection layer 180 may only cover the first flat surface E1; as shown in FIG. 22, the protection layer 180 may completely cover the peripheral side E; as shown in FIG. 23, the protection layer 180 may only cover the first flat surface E1 and the second oblique surface E3 without covering the first oblique surface E2; as shown in FIG. 24, the protection layer 180 may only cover the first flat surface E1 and the first oblique surface E2 without covering the second oblique surface E3. In addition, as shown in FIG. 25, the peripheral side E may also be a curved surface, and the curved peripheral side E may be regarded as a so-called “R angle”, but not limited thereto. As shown in FIG. 25, the protection layer 180 may completely cover the peripheral side E which is a curved surface. As shown in FIG. 26, the protection layer 180 may only cover a center part of the peripheral side E which is a curved surface. FIG. 27, the protection layer 180 may only cover the center part of the peripheral side E and a region adjacent to the fourth surface 130B. FIG. 28, the protection layer 180 may only cover the center part of the peripheral side E and a region adjacent to the third surface 130A.

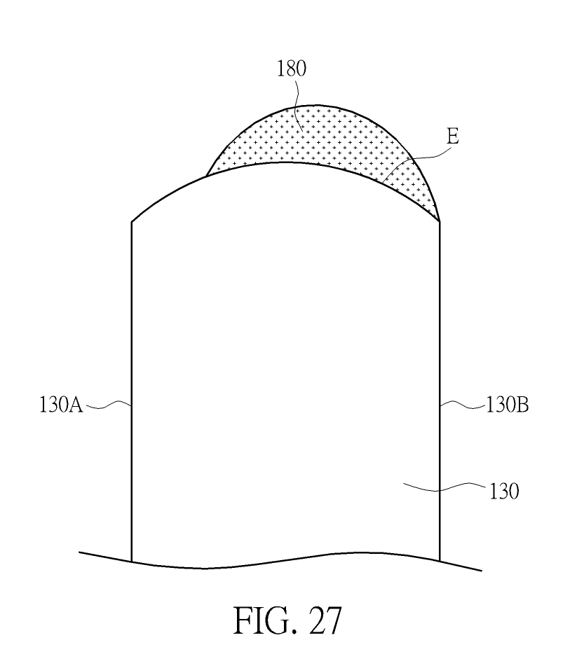

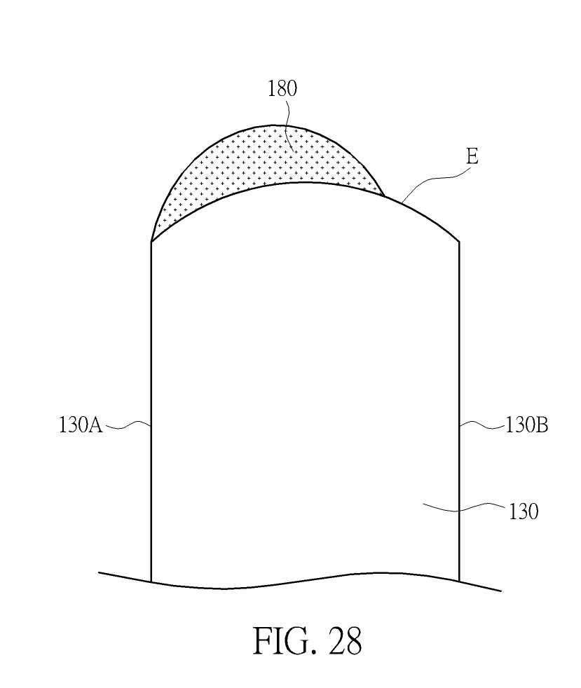

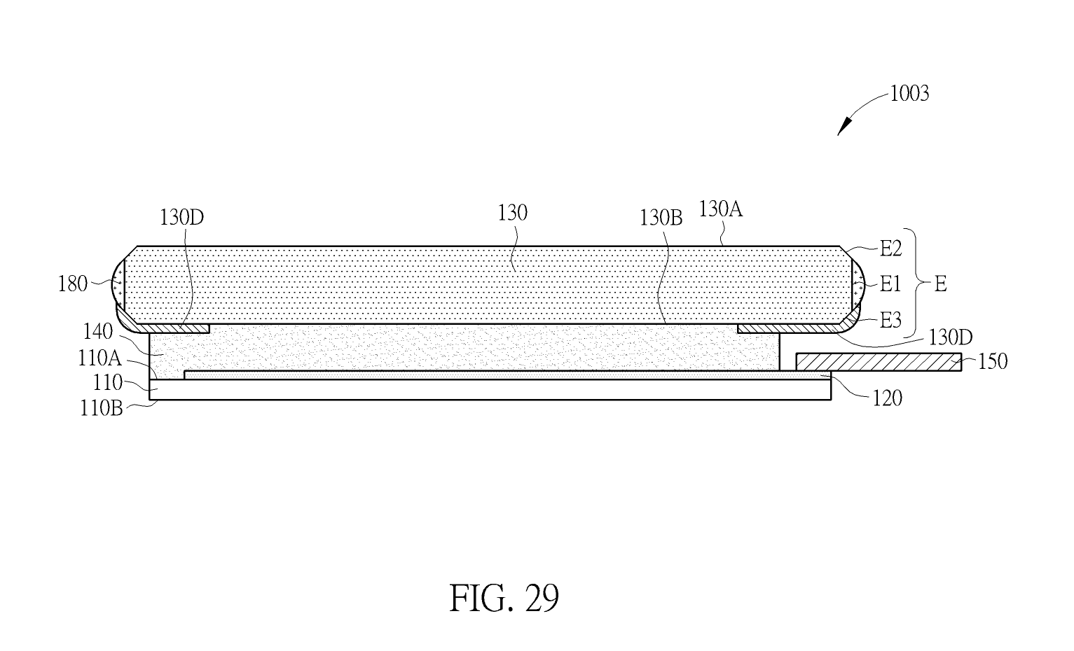

FIG. 29 is a schematic diagram illustrating a touch device 1003 according to an eighteenth embodiment of the present invention. As shown in FIG. 29, the difference between the touch device 1003 and the touch device in the seventeenth embodiment is that the protection layer 180 in this embodiment at least partially disposed between the decoration layer 130D and the cover substrate 130. In other words, the protection layer 180 may be formed on the cover substrate 130 and cover the peripheral side E before the process of forming the decoration layer 130D so as to ensure the mechanical strength of the cover substrate 130 during the manufacturing process of the decoration layer 130D and the decoration effects on the edge region of the cover substrate 130.

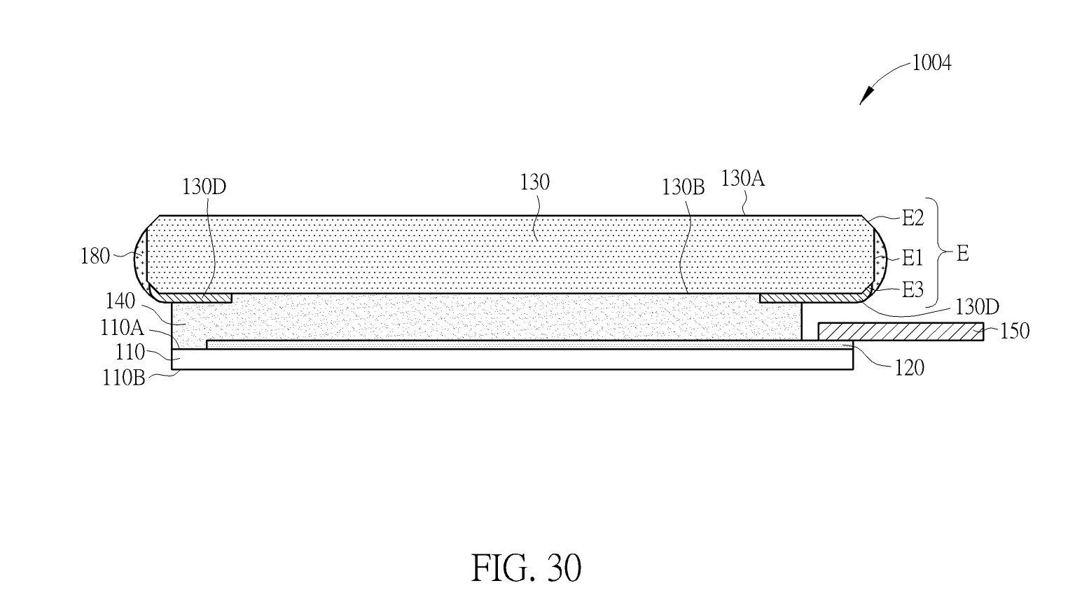

FIG. 30 is a schematic diagram illustrating a touch device 1004 according to a nineteenth embodiment of the present invention. As shown in FIG. 30, the difference between the touch device 1004 and the touch device in the eighteenth embodiment is that the protection layer 180 in this embodiment at least partially covers the decoration layer 130D, and the decoration layer 130D is partially disposed between the protection layer 180 and the cover substrate 130 preferably. In other words, the decoration layer 130D may be formed on the cover substrate 130 and cover the peripheral side E before the process of forming the protection layer 180 so as to ensure the decoration effects on the edge region of the cover substrate 130.

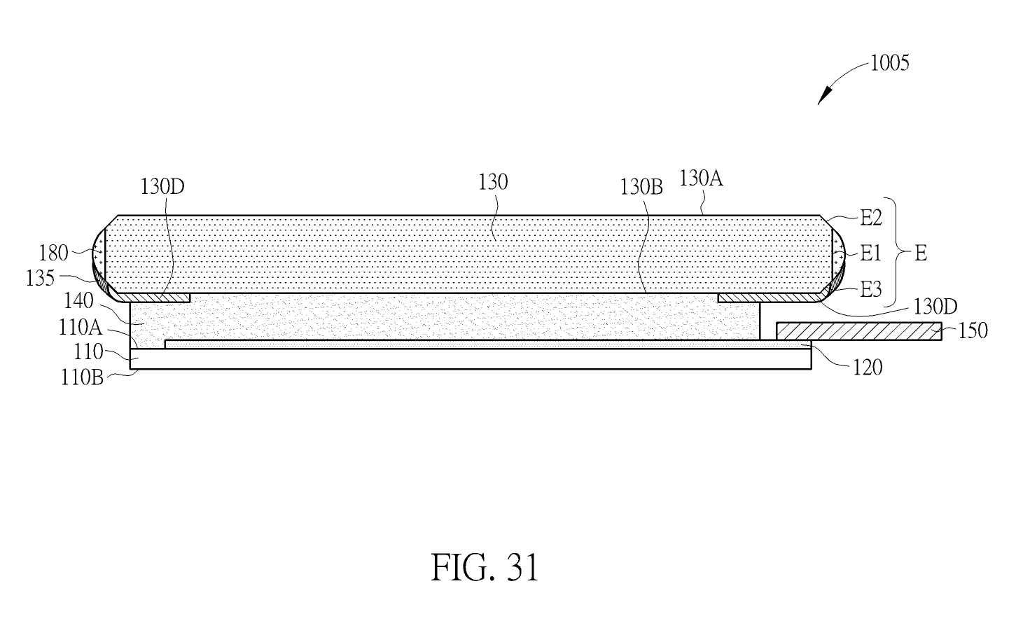

FIG. 31 is a schematic diagram illustrating a touch device 1005 according to a twentieth embodiment of the present invention. As shown in FIG. 31, the difference between the touch device 1005 and the touch device in the seventh embodiment is that the touch device 1005 further includes a shielding structure 135 disposed on the cover substrate 130 and at least partially covering the decoration layer 130D. The shielding structure 135 may be made of a translucent material, low light-permeable material, a light-impermeable material or an infrared permeable material so as to improve light leakage issues on the edges. For example, the shielding structure 135 may include a single layer structure or a multiple layered structure of a photoresist material, a diamond-like material, a ceramic material, an ink material or other appropriate shielding materials. Additionally, the protection layer 180 in this embodiment is at least partially disposed between the shielding structure 135 and the cover substrate 130, and the shielding structure 135 at least partially covers the protection layer 180. In other words, the protection layer 180 in this embodiment may be formed on the cover substrate 130 and cover the peripheral side E before the process of forming the shielding structure 135 so as to ensure the mechanical strength of the cover substrate 130 during the manufacturing process of the shielding structure 135 and the decoration effects on the edge region of the cover substrate 130.

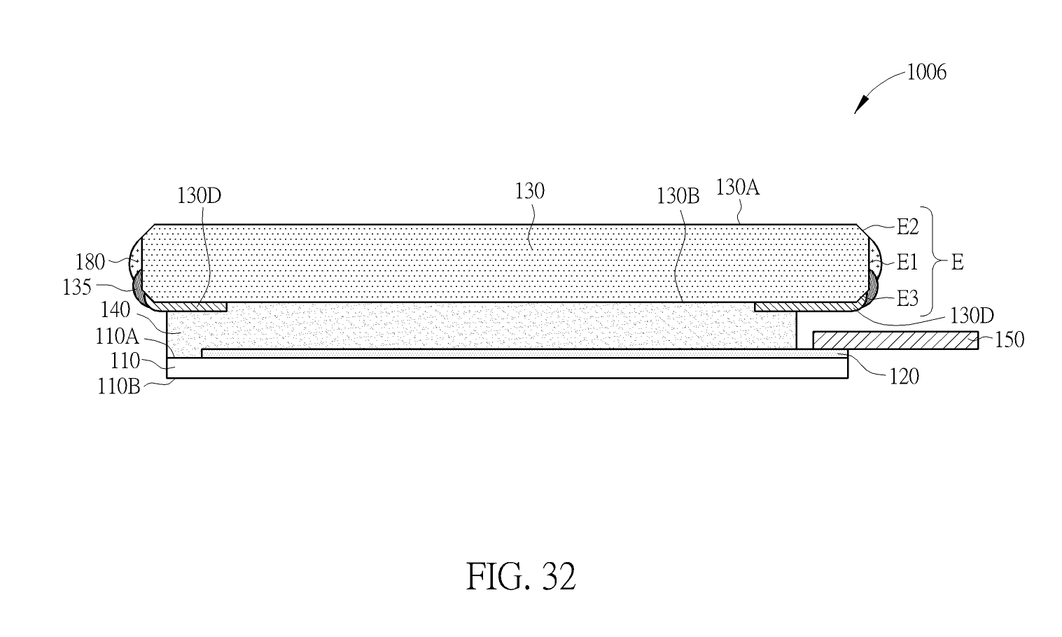

FIG. 32 is a schematic diagram illustrating a touch device 1006 according to a twenty-first embodiment of the present invention. As shown in FIG. 32, the difference between the touch device 1006 and the touch device in the twentieth embodiment is that the protection layer 180 in this embodiment at least partially covers the shielding structure 135, and the shielding structure 135 is partially disposed between the protection layer 180 and the cover substrate 130 preferably. In other words, the shielding structure 135 in this embodiment may be formed on the cover substrate 130 and partially cover the peripheral side E before the process of forming the protection layer 180 so as to ensure the decoration effects on the edge region of the cover substrate 130.

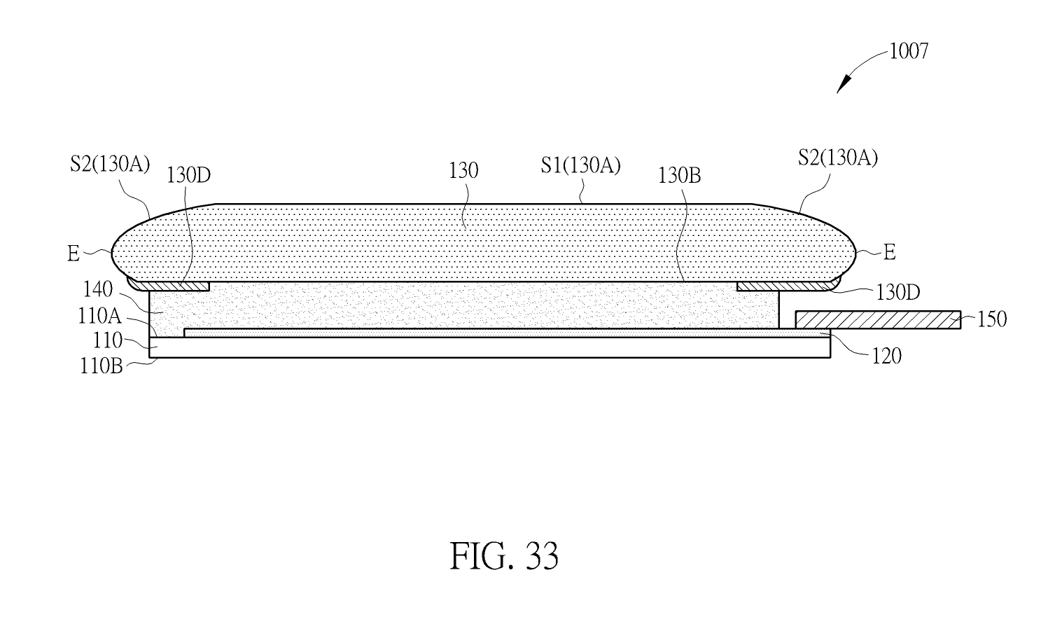

FIG. 33 is a schematic diagram illustrating a touch device 1007 according to a twenty-second embodiment of the present invention. As shown in FIG. 33, the difference between the touch device 1007 and the touch device in the sixteenth embodiment is that the third surface 130A of the cover substrate 130 may include a second flat surface S1 and a first curved surface S2, and the fourth surface 130B is a flat surface. The cover substrate 130 in this embodiment may be regarded as a so-called “2.25D substrate”, but not limited thereto.

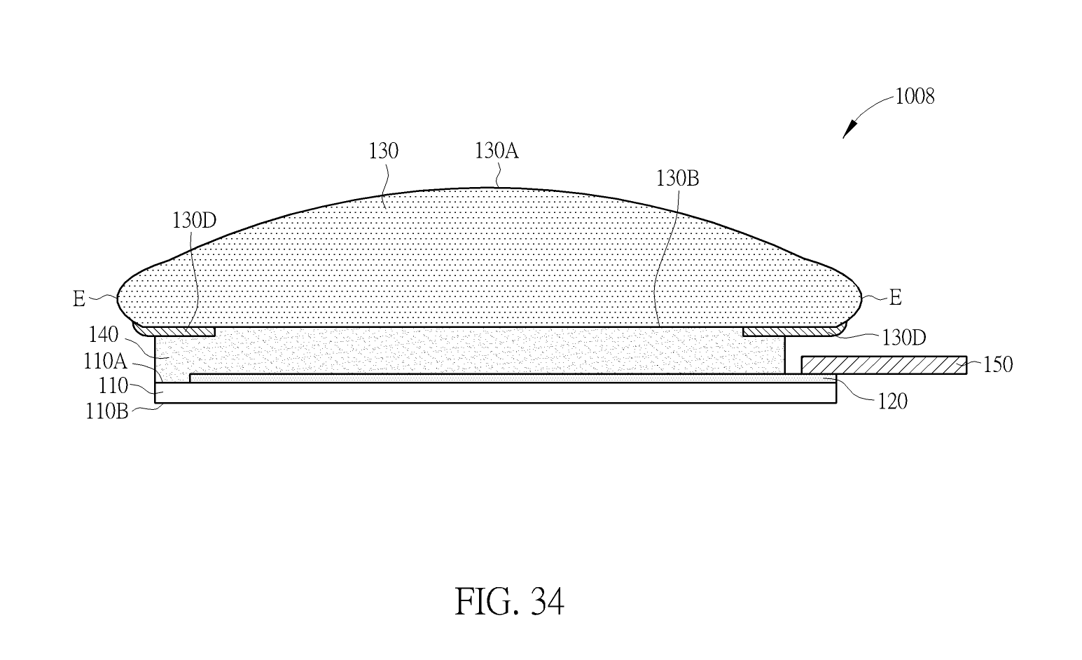

FIG. 34 is a schematic diagram illustrating a touch device 1008 according to a twenty-third embodiment of the present invention. As shown in FIG. 34, the difference between the touch device 1008 and the touch device in the sixteenth embodiment is that the third surface 130A of the cover substrate 130 in this embodiment is a curved surface, and the fourth surface 130B is a flat surface. The cover substrate 130 in this embodiment may be regarded as a so-called “2.5D substrate”, but not limited thereto.

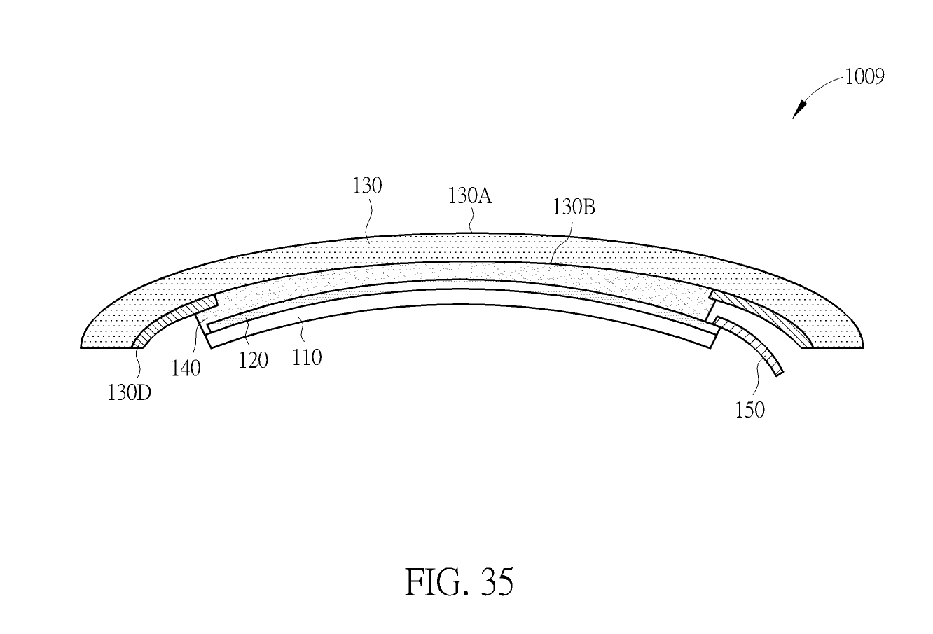

FIG. 35 is a schematic diagram illustrating a touch device 1009 according to a twenty-fourth embodiment of the present invention. As shown in FIG. 35, the difference between the touch device 1009 and the touch device in the sixteenth embodiment is that the third surface 130A of the cover substrate 130 in this embodiment may be a curved surface, and the fourth surface 130B may be another curved surface. The cover substrate 130 in this embodiment may be regarded as a so-called “3D substrate”, but not limited thereto. It is worth noting that the 2.25D cover substrate, the 2.5D cover substrate and the 3D cover substrate mentioned above may also be applied to other embodiments mentioned above or being described below according to other design considerations.

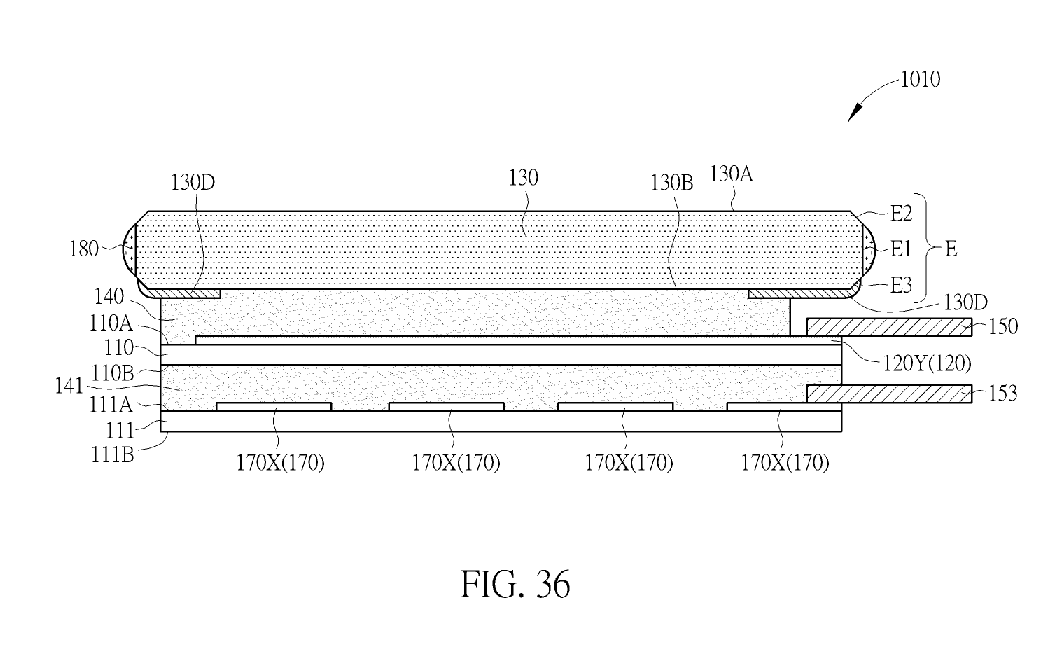

FIG. 36 is a schematic diagram illustrating a touch device 1010 according to a twenty-fifth embodiment of the present invention. As shown in FIG. 36, the difference between the touch device 1010 and the touch device in the seventeenth embodiment is that the touch device 1010 further includes a first substrate 111, a second adhesive layer 141 and a conductive layer 170. The first substrate 111 is disposed on a side of the second surface 110B of the thin substrate 110. The first substrate 111 has a fifth surface 111A and a sixth surface 111B opposite to the fifth surface 111A, and the fifth surface 111A faces the thin substrate 110. In this embodiment, the thin substrate 110 is disposed between the cover substrate 130 and the first substrate 111. The second adhesive layer 141 is disposed between the first substrate 111 and the thin substrate 110 so as to combine the first substrate 111 and the thin substrate 110. The conductive layer 170 is disposed on the first substrate 111. In other words, the conductive layer 170 may be formed on the first substrate 111 before the first substrate 111 is adhered to the thin substrate 110 via the second adhesive layer 141 for forming a dual side electrode structure. The material properties of the second adhesive layer 141 is similar to those of the first adhesive layer 140 mentioned above and will not be redundantly described.

It is worth noting that the conductive layer 170 may be collocated with the first touch sensing unit 120 for performing touch sensing operations, or the conductive layer 170 and the first touch sensing unit 120 may be used to perform different and independent touch sensing operations respectively. For example, the first touch sensing unit 120 may include the second axis electrodes 120Y described above, and the conductive layer 170 may include a plurality of third axis electrodes 170X crossing the second axis electrodes 120Y and electrically isolated from the second axis electrodes 120Y. Each of the third axis electrodes 170X extends along the first direction X. The allocation of the third axis electrodes 170X is similar to that of the first axis electrodes 120X shown in FIG. 4. The third axis electrodes 170 may be collocated with the second axis electrodes 120Y so as to perform a touch sensing & positioning function, but not limited thereto. In addition, because the conductive layer 170 is disposed on the lower part of the touch device and relatively closer to a display device (not shown), the conductive layer 170 may also be used to reduce signal interference from the display device disposed below, but not limited thereto. Accordingly, a width of the third axis electrode 170X may be wider than or equal to a width of each second axis electrode 120Y when the conductive layer 170 is used as a touch signal driving electrode and the first touch sensing unit 120 is used as a touch signal receiving electrode, or a covering area of the third axis electrodes 170X corresponding to the first substrate 111 may be larger than or equal to a covering area of the second axis electrodes 120Y corresponding to the first substrate 111, but not limited thereto. In addition, apart from being collocated with the first touch sensing unit 120 for touch sensing operations, the conductive layer 170 may also be a conductive film layer used as an interference shielding layer configured to isolate signal interference from other devices, such as signal interference from a display device. The conductive layer 170 may be a transparent conductive layer or a mesh conductive layer. Additionally, a low resistance material layer (not shown in FIG. 36), which is electrically connected to a grounding end, may be disposed on at least one side of the periphery of the conductive layer 170 and disposed correspondingly to the decoration layer 130D preferably so as to assist in passing the outer interference signal toward the grounding end. The interference signals may flow rapidly to the grounding end because the resistance of the low resistance material layer is lower than that of the conductive layer 170. The low resistance material layer is disposed to surround the periphery of the conductive layer 170 preferably, and a sheet resistance of the low resistance material layer is lower than 30Ω/□ preferably. The material of the low resistance material layer may include at least one of aluminum, copper, silver, chromium, titanium, and molybdenum, a composite layer of the materials mentioned above or an alloy of the materials mentioned above, but not limited thereto. Additionally, the conductive layer 170 in this embodiment is disposed on the fifth surface 111A of the first substrate 111, and the first touch sensing unit 120 is disposed on the first surface 110A of the thin substrate 110, but the present invention is not limited to this. In other embodiments of the present invention, the first touch sensing unit 120 and the conductive layer 170 may also be disposed on different surfaces of the thin substrate 110 and the first substrate 111 respectively so as to perform the required touch sensing functions. It is worth noting that the first substrate 111 may include a thin film layer, a thin substrate, a substrate having normal thickness (about 0.3 mm to 0.7 mm) or a substrate of a display device. The thin film layer mentioned above may include a polyimide (PI) film or a photoresist film, a thin substrate. The thin substrate mentioned above may include a thin glass substrate, a thin plastic substrate, a thin glass-plastic composite substrate or other thin substrate made of appropriate materials. The substrate having normal thickness mentioned above may include a glass substrate, a ceramic substrate or a plastic substrate. Additionally, the touch device 1010 in this embodiment may further include a fourth outer unit 153 electrically connected to the conductive layer 170. The fourth outer unit 153 may include a flexible printed circuit, an integrated circuit or other outer unit electrically connected to the conductive layer 170. The fourth outer unit 153 may also be integrated with the first outer unit 150 to be a single outer unit, but not limited thereto.

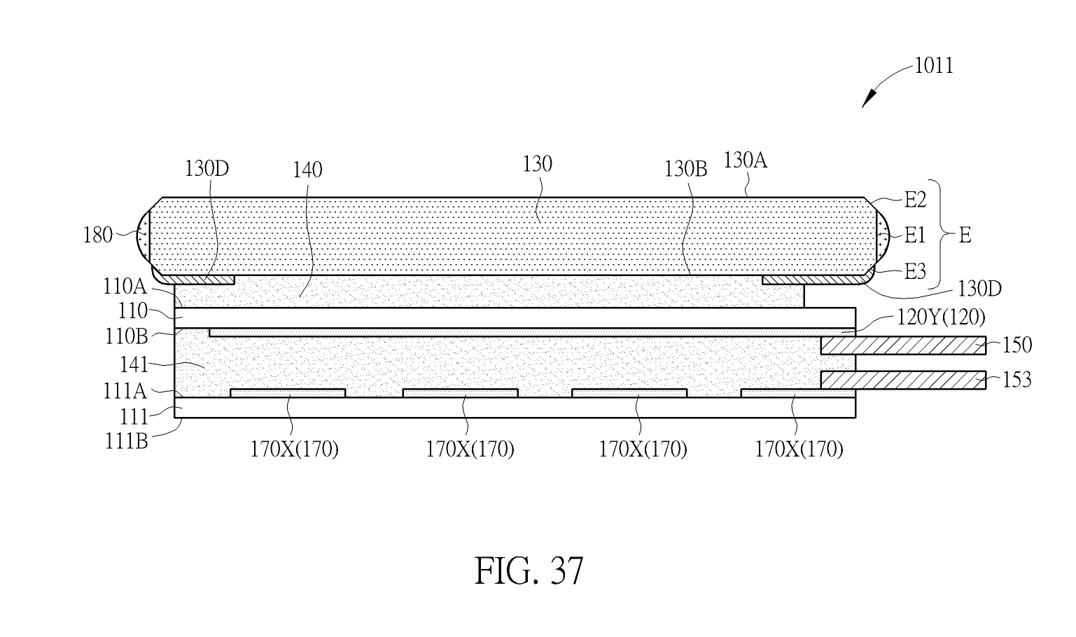

FIG. 37 is a schematic diagram illustrating a touch device 1011 according to a twenty-sixth embodiment of the present invention. As shown in FIG. 37, the difference between the touch device 1011 and the touch device in the twenty-fifth embodiment is that the first touch sensing unit 120 and the first outer unit 150 in this embodiment are disposed on a side of the second surface 110B of the thin substrate 110. In other words, the first touch sensing unit 120 is disposed to face the conductive layer 170.

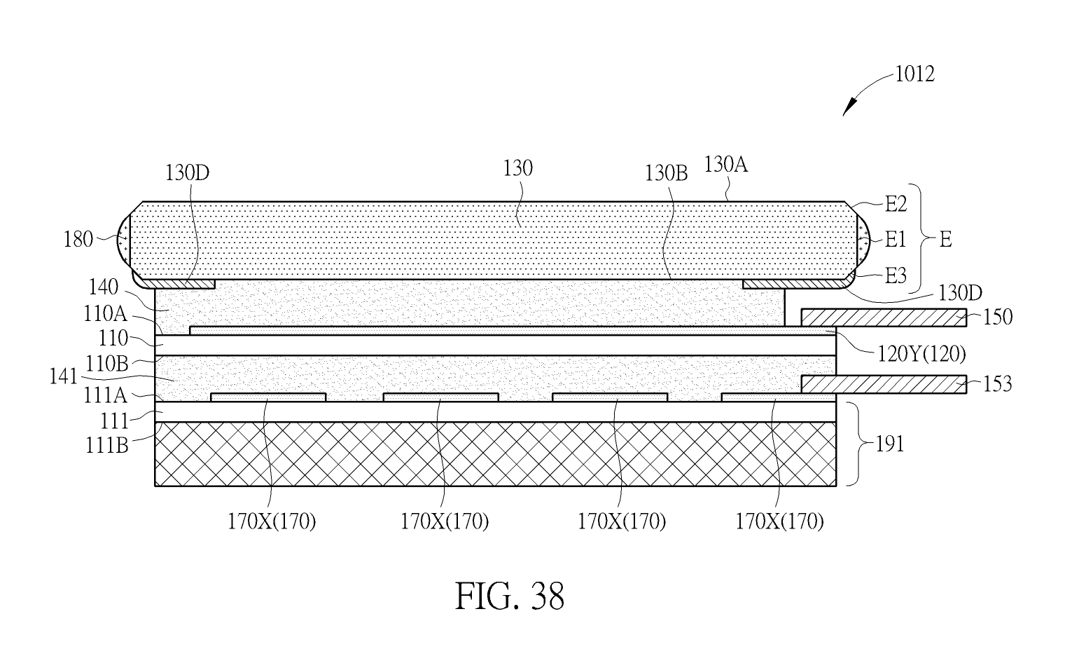

FIG. 38 is a schematic diagram illustrating a touch device 1012 according to a twenty-seventh embodiment of the present invention. As shown in FIG. 38, the difference between the touch device 1012 and the touch device in the twenty-fifth embodiment is that the first substrate 111 in this embodiment is a substrate of a display device 191. The display device 191 may include a liquid crystal display device, an organic light emitting diode display device, an electro-wetting display device, an e-ink display device, a plasma display device, a field emission display device or other appropriate display devices. The conductive layer 170 may be disposed on the fifth surface 111A of the first substrate 111 so as to form an on-cell type touch display device, but the present invention is not limited to this. In other embodiments of the present invention, the conductive layer 170 may also be disposed on the sixth surface 111B of the first substrate 111 and disposed in the display device 191 so as to form an in-cell type touch display device.

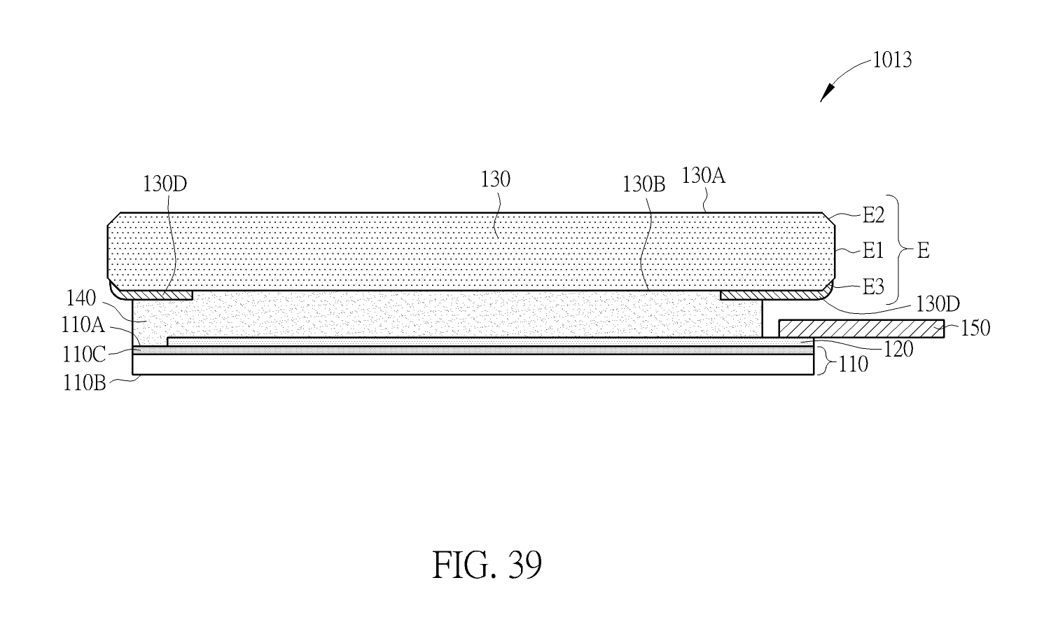

FIG. 39 is a schematic diagram illustrating a touch device 1013 according to a twenty-eighth embodiment of the present invention. As shown in FIG. 39, the difference between the touch device 1013 and the touch device in the sixteenth embodiment is that the thin substrate 110 in this embodiment further has a break cutting line 110C on a side of the first surface 110A. The break cutting line 110C is a structure formed during the process of forming the thin substrate 110 by cutting with a cutter wheel. In this embodiment, the break cutting line 110C is not disposed to be exposed at the outer side of the touch device 1013. The first surface 110A with the break cutting line 110C is disposed to face up and face the cover substrate 130, and the second surface 110B without the break cutting line is disposed to face down. The second surface 110B is smoother than the first surface 110A, and the pressure resistance of the second surface 110B is relatively high. Accordingly, the second surface 110B will not be broken or damaged easily under the condition of applying force and deformation. The first touch sensing unit 120 in this embodiment is disposed on the first surface 110A. In other words, the first touch sensing unit 120 may be disposed closer to a side of the break cutting line 110C, but not limited thereto. The first touch sensing unit 120 may also be disposed on the second surface 110B or be disposed on the first surface 110A and the second surface 110B.

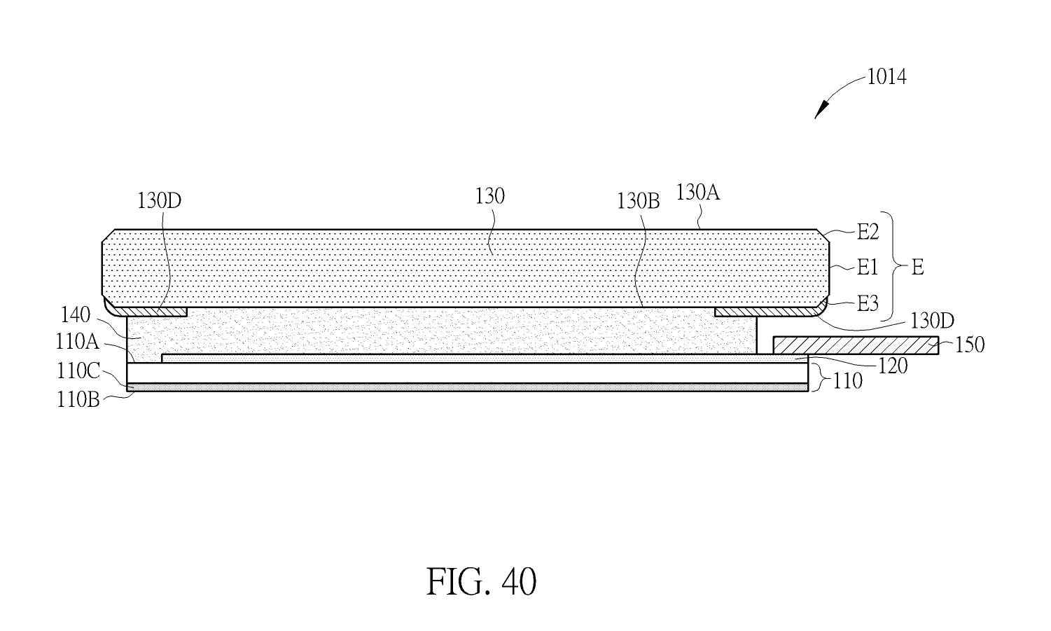

FIG. 40 is a schematic diagram illustrating a touch device 1014 according to a twenty-ninth embodiment of the present invention. As shown in FIG. 40, the difference between the touch device 1014 and the touch device in the twenty-eighth embodiment is that the break cutting line 110C is disposed on a side of the second surface 110B.

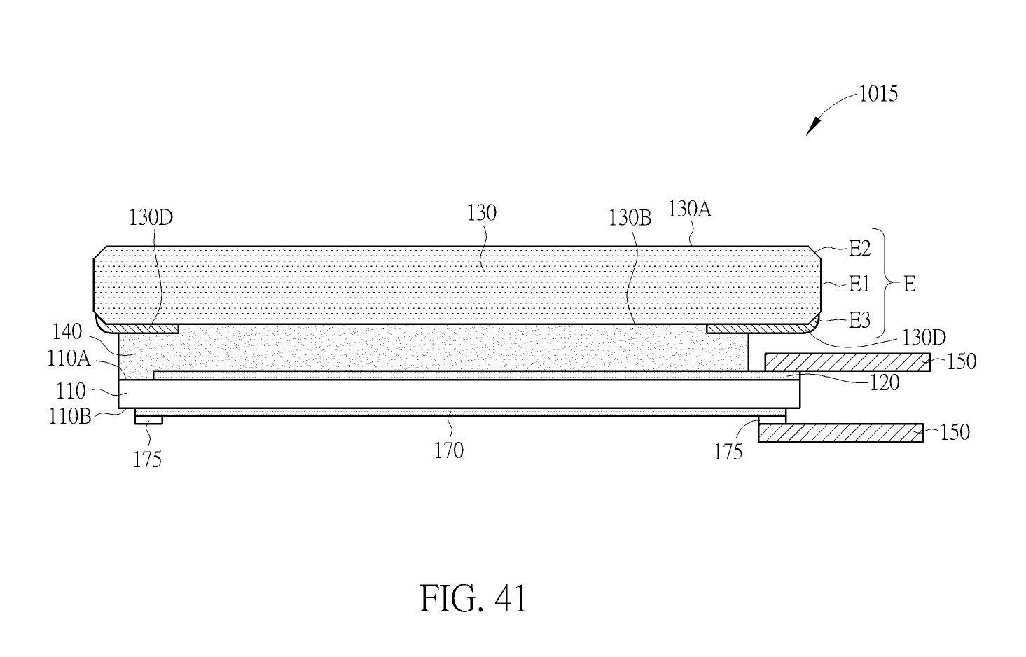

FIG. 41 is a schematic diagram illustrating a touch device 1015 according to a thirtieth embodiment of the present invention. As shown in FIG. 41, the difference between the touch device 1015 and the touch device in the twenty-ninth embodiment is that the touch device 1015 further includes a conductive layer 170 disposed on the second surface 110B of the thin substrate 110. The conductive layer 170 is disposed on a lower part of the touch device 1015 and disposed closer to the display device (not shown). Signals from the display device may interfere with the sensing operation of the touch device 1015, and the conductive layer 170 may be an interference shielding layer configured to isolate the touch device from interference of the display device. The conductive layer 170 may be a transparent conductive layer or a mesh conductive layer. Additionally, a low resistance material layer 175, which is electrically connected to a grounding end preferably, may be disposed on at least one side of the periphery of the conductive layer 170 and disposed correspondingly to the decoration layer 130D preferably so as to assist in passing the outer interference signal toward the grounding end. The interference signals may flow rapidly to the grounding end because the resistance of the low resistance material layer 175 is lower than that of the conductive layer 170. The low resistance material layer 175 is disposed to surround the periphery of the conductive layer 170 preferably, and a sheet resistance of the low resistance material layer 175 is lower than 30Ω/□ preferably. The material of the low resistance material layer 175 may include at least one of aluminum, copper, silver, chromium, titanium, and molybdenum, a composite layer of the materials mentioned above or an alloy of the materials mentioned above, but not limited thereto.

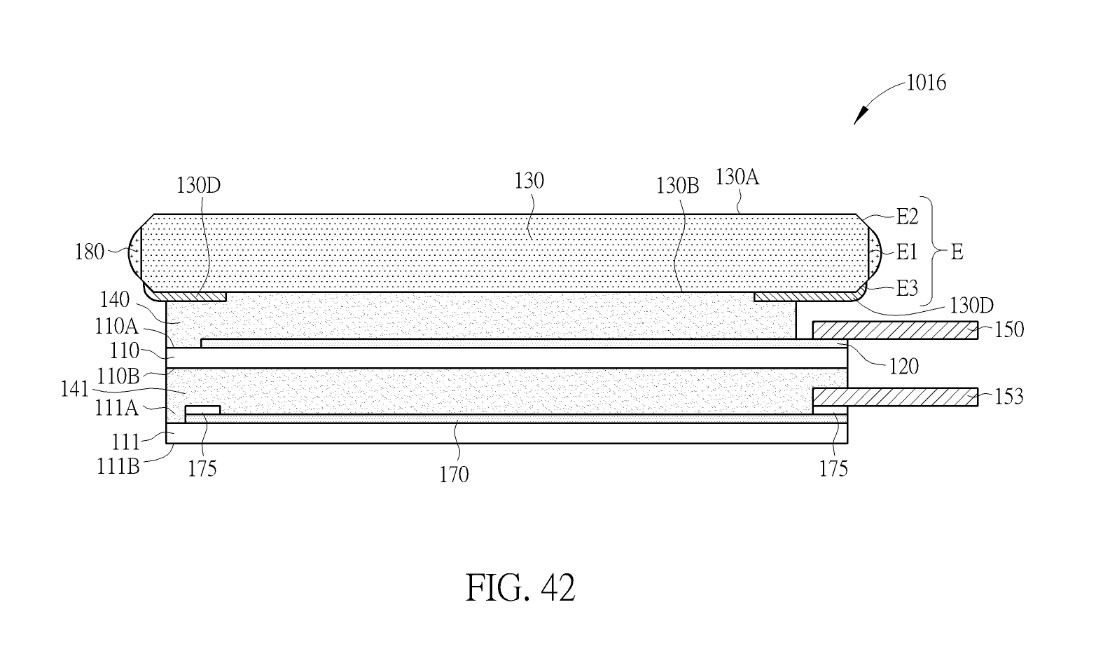

FIG. 42 is a schematic diagram illustrating a touch device 1016 according to a thirty-first embodiment of the present invention. As shown in FIG. 42, the difference between the touch device 1016 and the touch device in the twenty-fifth embodiment is that the conductive layer 170 is only an interference shielding layer configured to isolate the touch device from interference of the outer signals. Additionally, the touch device 1016 may further include a low resistance material layer 175, which is electrically connected to a grounding end preferably, disposed on at least one side of the periphery of the conductive layer 170 and disposed correspondingly to the decoration layer 130D preferably so as to assist in passing the outer interference signal toward the grounding end. The interference signals may flow rapidly to the grounding end because the resistance of the low resistance material layer 175 is lower than that of the conductive layer 170. The low resistance material layer 175 is disposed to surround the periphery of the conductive layer 170 preferably, and a sheet resistance of the low resistance material layer 175 is lower than 30Ω/□ preferably. The material of the low resistance material layer 175 may include at least one of aluminum, copper, silver, chromium, titanium, and molybdenum, a composite layer of the materials mentioned above or an alloy of the materials mentioned above, but not limited thereto. It is worth noting that the conductive layer 170 and the low resistance material layer 175 may also be modified to be disposed on a side of the sixth surface 111B of the first substrate 111 so as to generate required interference shielding effect.

The thin substrate in the above mentioned embodiments may be flexible and include a thin glass substrate, a thin plastic substrate or a thin glass-plastic composite substrate with thickness thicker than or equal to 0.05 mm and thinner than or equal to 0.25 mm. In addition, the cover substrate may include glass cover substrate (such as a tempered glass), a plastic cover substrate or other cover substrates made of materials with high mechanical strength and used to protect, cover or decorate the corresponding device. The shape of the cover substrate may be flat, curved or the combination thereof, such as a 2.5D glass, but not limited thereto. A protection layer, such as a light-cured adhesive, may be spread or coated on the peripheral sides of the cover substrate may be covered so as to enhance the mechanical strength of the cover substrate and resist damages from outside force. A decoration layer may be further disposed on the cover substrate, and the decoration layer may be disposed in the peripheral region. The decoration layer may be a black decoration layer or a color decoration layer so as to present decoration effects on the cover substrate. The first adhesive layer may include a liquid optical clear adhesive (LOCA), a solid optical clear adhesive (OCA), a pressure sensitive adhesive (PSA) or other appropriate adhesive materials. The first outer unit, the second outer unit and the third outer unit may include a flexible printed circuit (FPC), an integrated circuit or other outer unit electrically connected to the touch sensing unit respectively. The first touch sensing unit and the second touch sensing unit may be formed by a transparent conductive material, a conductive mesh or other appropriate conductive materials.

It is worth noting that the descriptions about disposing on the surface of the substrate are not limited to the condition of directly contacting the surface of the substrate.

To summarize the above descriptions, in the touch device of the present invention, the touch sensing unit is disposed on the thin substrate having a thickness thicker than or equal to 0.05 millimeter and thinner than or equal to 0.25 millimeter so as achieve the purposes of lightweight and thinner designs. Additionally, the thin substrate in the present invention may also be used as a substrate of the display device, and the touch sensing unit may be disposed on the thin substrate of the display device for forming a thin integrated touch display device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A touch device, comprising:
a cover substrate;
a thin substrate, disposed opposite to the cover substrate, wherein the thin substrate has a first surface and a second surface opposite to the first surface, the first surface faces the cover substrate, and a thickness of the thin substrate is thicker than or equal to 0.05 millimeter and thinner than or equal to 0.25 millimeter;
a first adhesive layer, disposed between the cover substrate and the thin substrate;
a first touch sensing unit, disposed on the thin substrate; and
a first outer unit, electrically connected to the first touch sensing unit.

2. The touch device of claim 1, wherein the first touch sensing unit and at least a part of the first outer unit are disposed on a side of the first surface.

3. The touch device of claim 2, further comprising a conductive layer, disposed on a side of the second surface.

4. The touch device of claim 3, further comprising a low resistance material layer, disposed on the conductive layer, wherein the low resistance material layer is disposed on at least one side of a periphery of the conductive layer.

5. The touch device of claim 4, wherein the low resistance material layer is disposed to surround the periphery of the conductive layer.

6. The touch device of claim 2, wherein a thickness of the first adhesive layer is thicker than or equal to a thickness of the first outer unit.

7. The touch device of claim 2, further comprising a display device, disposed on a side of the second surface of the thin substrate, wherein the first outer unit comprises a first connection end and a second connection end, the first connection end is disposed on the first surface of the thin substrate so as to be electrically connected to the first touch sensing unit, and the second connection end is electrically connected to the display device.

8. The touch device of claim 1, wherein the first touch sensing unit and at least a part of the first outer unit are disposed on a side of the second surface.

9. The touch device of claim 8, further comprising a display device, disposed on a side of the second surface of the thin substrate, wherein the first outer unit comprises a first connection end and a second connection end, the first connection end is disposed on the second surface of the thin substrate so as to be electrically connected to the first touch sensing unit, and the second connection end is electrically connected to the display device.

10. The touch device of claim 8, wherein a thickness of the first adhesive layer is thinner than a thickness of the first outer unit.

11. The touch device of claim 1, wherein the thin substrate comprises a thin glass substrate, a thin plastic substrate or a thin glass-plastic composite substrate.

12. The touch device of claim 1, wherein the thin substrate comprises a substrate of a display device, and the substrate of the display device comprises a color filter substrate, an array substrate or an encapsulating substrate of an organic light emitting display device.

13. The touch device of claim 1, further comprising a decoration layer, disposed on the cover substrate, wherein the cover substrate has a light-permeable region and a peripheral region disposed on at least one side of the light-permeable region, and the decoration layer is disposed in the peripheral region.

14. The touch device of claim 1, further comprising:
a supporting substrate, disposed on the cover substrate; and
a decoration layer, disposed on the supporting substrate, wherein the cover substrate has a light-permeable region and a peripheral region disposed on at least one side of the light-permeable region, and the decoration layer is disposed correspondingly to the peripheral region.

15. The touch device of claim 1, further comprising:
a supporting substrate, disposed on a side of the cover substrate facing the thin substrate; and
a decoration layer, disposed on the supporting substrate, wherein the cover substrate has a light-permeable region and a peripheral region disposed on at least one side of the light-permeable region, and the decoration layer is disposed correspondingly to the peripheral region.

16. The touch device of claim 1, further comprising a conductive protection line, disposed on the cover substrate.

17. The touch device of claim 16, wherein the first outer unit comprises a third connection end, and the first outer unit is electrically connected to the conductive protection line via the third connection end.

18. The touch device of claim 16, further comprising a second outer unit, electrically connected to the conductive protection line.

19. The touch device of claim 1, further comprising a second touch sensing unit, disposed on the cover substrate.

20. The touch device of claim 19, wherein the first outer unit comprises a fourth connection end, and the first outer unit is electrically connected to the second touch sensing unit via the fourth connection end.

21. The touch device of claim 19, further comprising a third outer unit, wherein the third outer unit is electrically connected to the second touch sensing unit.

22. The touch device of claim 1, wherein the first touch sensing unit comprises a plurality of touch electrodes disposed to be electrically isolated from one another.

23. The touch device of claim 22, wherein the touch electrodes comprise at least one touch signal driving electrode and at least one touch signal receiving electrode.

24. The touch device of claim 1, wherein the first touch sensing unit comprises:
a plurality of first axis electrodes, extending along a first direction; and
a plurality of second axis electrodes, extending along a second direction, wherein the second axis electrodes are electrically isolated from the first axis electrodes.

25. The touch device of claim 24, further comprising an insulation layer, disposed between the first axis electrode and the second axis electrode so as to electrically isolate the first axis electrodes from the second axis electrodes.

26. The touch device of claim 24, wherein the first axis electrodes are disposed on the first surface of the thin substrate, and the second axis electrodes are disposed on the second surface of the thin substrate.

27. The touch device of claim 24, wherein a width of at least one of the second axis electrodes is wider than or equal to a width of each first axis electrode.

28. The touch device of claim 24, wherein a covering area of the second axis electrodes on the thin substrate is larger than or equal to a covering area of the first axis electrodes on the thin substrate.

29. The touch device of claim 24, wherein the second axis electrodes are an interference shielding layer.

30. The touch device of claim 24, wherein each of the first axis electrodes comprises a plurality of first sub-electrodes and at least one first connecting line disposed between two adjacent first sub-electrodes, and the first connecting line is configured to electrically connect the two adjacent first sub-electrodes; each of the second axis electrodes comprises a plurality of second sub-electrodes and at least one second connecting line disposed between two adjacent second sub-electrodes, and the second connecting line is configured to electrically connect the two adjacent second sub-electrodes.

31. The touch device of claim 30, further comprising at least one insulation block, disposed between the first connecting line and the second connecting line so as to electrically isolate the first axis electrodes from the second axis electrodes.

32. The touch device of claim 1, wherein the first touch sensing unit comprises a transparent conductive material or conductive mesh.

33. The touch device of claim 1, wherein the first outer unit comprises a flexible printed circuit (FPC).

34. The touch device of claim 1, further comprising a protection layer, disposed on at least one peripheral side of the cover substrate.

35. The touch device of claim 1, further comprising a decoration layer, disposed on the cover substrate, wherein the cover substrate has a peripheral side, a third surface and a fourth surface opposite to the third surface, the fourth surface faces the thin substrate, and the decoration layer at least partially covers the fourth surface.

36. The touch device of claim 35, wherein the decoration layer comprises a single layer structure or a multiple layered structure of a photoresist material, a diamond-like material, a ceramic material or an ink material.

37. The touch device of claim 35, further comprising a light-shielding layer, disposed on the decoration layer.

38. The touch device of claim 35, wherein the peripheral side of the cover substrate comprises a first flat surface, a first oblique surface and a second oblique surface, the first oblique surface is connected to the third surface, the second oblique surface is connected to the fourth surface, and the first flat surface is disposed between the first oblique surface and the second oblique surface.

39. The touch device of claim 38, further comprising a protection layer, disposed on the peripheral side of the cover substrate, wherein the protection layer at least partially covers the first flat surface, the first oblique surface or/and the second oblique surface.

40. The touch device of claim 39, wherein the protection layer is at least partially disposed between the decoration layer and the cover substrate.

41. The touch device of claim 39, wherein the protection layer is at least partially covers the decoration layer.

42. The touch device of claim 39, further comprising a shielding structure, disposed on the cover substrate and at least partially covering the decoration layer.

43. The touch device of claim 42, wherein the shielding structure comprises a translucent material, a low light-permeable material, a light-impermeable material or an infrared permeable material.

44. The touch device of claim 42, wherein the shielding structure comprises a single layer structure or a multiple layered structure of photoresist materials, diamond-like materials, ceramic materials or ink materials.

45. The touch device of claim 42, wherein the protection layer is at least partially disposed between the shielding structure and the cover substrate.

46. The touch device of claim 42, wherein the protection layer at least partially covers the shielding structure.

47. The touch device of claim 35, wherein the third surface and the fourth surface of the cover substrate are a flat surface, a curved surface or a combination of a flat surface and a curved surface respectively.

48. The touch device of claim 1, further comprising:
a first substrate, disposed on a side of the second surface of the thin substrate, wherein the first substrate has a fifth surface and a sixth surface opposite to the fifth surface, and the fifth surface faces the thin substrate;
a second adhesive layer, disposed between the first substrate and the thin substrate; and
a conductive layer, disposed on the first substrate.

49. The touch device of claim 48, wherein the first touch sensing unit comprises a plurality of second axis electrodes extending along a second direction, and the conductive layer comprises a plurality of third axis electrodes extending along a first direction, wherein the third axis electrodes cross the second axis electrodes, and the third axis electrodes are electrically isolated from the second axis electrodes.

50. The touch device of claim 49, wherein a width of at least one of the third axis electrodes is wider than or equal to a width of each second axis electrode.

51. The touch device of claim 49, wherein a covering area of the third axis electrodes corresponding to the first substrate is larger than or equal to a covering area of the second axis electrodes corresponding to the first substrate.

52. The touch device of claim 48, wherein the first substrate comprises a thin film layer, a thin glass substrate, a thin plastic substrate or a thin glass-plastic composite substrate.

53. The touch device of claim 52, wherein the thin film layer comprises a polyimide (PI) film or a photoresist film.

54. The touch device of claim 48, wherein the first substrate comprises a glass substrate, a ceramic substrate, a plastic substrate or a substrate of a display device.

55. The touch device of claim 48, wherein the conductive layer is an interference shielding layer.

56. The touch device of claim 55, further comprising a low resistance material layer, disposed on the conductive layer, wherein the low resistance material layer is disposed on at least one side of a periphery of the conductive layer.

57. The touch device of claim 56, wherein the low resistance material layer is disposed to surround the periphery of the conductive layer.

58. The touch device of claim 1, wherein the thin substrate further has a break cutting line on a side of the first surface, and the first touch sensing unit is disposed on the first surface.
